(19) United States
(12) Patent Application Publication
(10) Pub. No.: US 2020/0072752 A1
(43) Pub. Date: Mar. 5, 2020

(54) SYSTEM AND METHODS FOR DETECTING LIFETIME USING PHOTON COUNTING PHOTODETECTORS

(71) Applicant: Quantum-Si Incorporated, Guilford, CT (US)

(72) Inventor: Benjamin Cipriany, Branford, CT (US)

(73) Assignee: Quantum-Si Incorporated, Guilford, CT (US)

(21) Appl. No.: 16/554,751

(22) Filed: Aug. 29, 2019

Related U.S. Application Data
(60) Provisional application No. 62/724,167, filed on Aug. 29, 2018.

(51) Int. Cl. G01N 21/64; H01L 31/107; G01N 21/27

(52) U.S. Cl. CPC G01N 21/6408; H01L 31/02024; G01N 21/27; H01L 31/107

(57) ABSTRACT

Systems and methods for detecting lifetime of luminescent molecules using photodetectors configured to perform photon counting are described. The systems and methods may involve an array of photodetectors for detecting photons emitted from a sample, which may include the luminescent molecules, and detection circuitry associated with the array of photodetectors. The detection circuitry may be configured to count, during at least a first time period and a second time period, a quantity of incident photons at a photodetector in the array of photodetectors.

### CROSS-REFERENCE TO RELATED APPLICATIONS

This application claims the benefit under 35 U.S.C. § 119(e) of U.S. Provisional Patent Application Ser. No. 62/724,167, titled “SYSTEM AND METHODS FOR DETECTING LIFETIME USING PHOTON COUNTING PHOTODETECTORS”, and filed on Aug. 29, 2018, which is incorporated by reference herein in its entirety.

### BACKGROUND

### Field

The present application relates to systems, methods, and techniques for detecting molecules in biological and chemical samples by performing parallel analysis of these samples.

### Related Art

Detection and analysis of biological and chemical samples may be performed by labeling samples with luminescent labels that emit light having a characteristic wavelength in response to illuminating the samples with light that excites the luminescent labels. Photodetectors positioned to detect the emitted light may generate signals, which may be used to analyze the sample.

### SUMMARY

Some embodiments are directed to a system including an array of photodetectors and detection circuitry associated with the array of photodetectors. The detection circuitry being configured to count, during a first time period and a second time period following illumination of a luminescent molecule with excitation light, a quantity of incident photons received from the luminescent molecule at a photodetector of the array of photodetectors.

In some embodiments, the detection circuitry is configured to count single photons incident to the array of photodetectors during the first time period and the second time period. In some embodiments, the detection circuitry is further configured to generate signals identifying the luminescent molecule.

In some embodiments, the detection circuitry is further configured to generate signals distinguishing among different types of luminescent molecules including a first signal identifying a first type of luminescent molecule and a second signal identifying a second type of luminescent molecule. In some embodiments, the different types of luminescent molecules are associated with different nucleotides, and the detection circuitry is configured to generate a set of signals identifying a series of nucleotides. In some embodiments, the set of signals identifying the series of nucleotides sequences a template nucleic acid molecule. In some embodiments, the series of nucleotides identified by the set of signals is a series of nucleotides of a nucleic acid molecule complementary to the template nucleic acid molecule. In some embodiments, different types of nucleotides in the series of nucleotides are labeled with the different types of luminescent molecules.

In some embodiments, the detection circuitry is further configured to generate signals indicative of a lifetime of the luminescent molecule.

In some embodiments, the detection circuitry has at least two photon counting circuits associated with a photodetector in the array and is configured to count the quantity of incident photons received by the photodetector. In some embodiments, the detection circuitry is further configured to generate signals indicative of the quantity of incident photons received by the photodetector during the first time period and the second time period. In some embodiments, the signals generated by the detection circuitry include a first signal identifying a first quantity of incident photons received by the photodetector during the first time period and a second signal identifying a second quantity of incident photons received by the photodetector during the second time period. In some embodiments, the at least two photon counting circuits includes a first photon counting circuit and a second photon counting circuit, and the first photon counting circuit is configured to generate the first signal and the second photon counting circuit is configured to generate the second signal. In some embodiments, the detection circuitry is configured to generate a readout signal that includes the first signal and the second signal. In some embodiments, the first time period and the second time period are non-overlapping time periods.

In some embodiments, the detection circuitry is configured to receive a control signal indicating a reference time and perform photon counting in response to receiving the control signal. In some embodiments, the detection circuitry is configured to receive a control signal from a light source configured to emit a pulse of the excitation light and perform photon counting in response to receiving the control signal.

In some embodiments, the system further comprises: at least one light source configured to emit the excitation light; and circuitry configured to control the at least one light source to emit pulses of excitation light and generate control signals corresponding to the emitted pulses. The detection circuitry associated with a photodetector in the array is configured to perform photon counting in response to receiving at least one of the control signals from the circuitry.

In some embodiments, the system further comprises: an array of sample wells, where individual sample wells in the array of sample wells are configured to receive a sample. In some embodiments, an alignment position of the array of sample wells to the array of photodetectors includes a first subset of sample wells positioned to optically align with at least a portion of the photodetectors in the photodetector array and a second subset of sample wells positioned to not optically align with photodetectors in the array of photodetectors. In some embodiments, the first subset of sample wells includes at least one row of sample wells in the array of sample wells that optically aligns with at least one row of photodetectors in the array of photodetectors when in the alignment position. In some embodiments, the first subset of sample wells includes a first row and a second row of sample wells in the array of sample wells, wherein the first row and the second row are separated by at least one row of sample wells in the second subset of sample wells.

In some embodiments, the system further comprises: at least one optic positioned to direct photons emitted from the array of sample wells towards the array of photodetectors. In some embodiments, the at least one optic is positioned to direct photons emitted from one sample well of the array of sample wells to one photodetector in the array of photodetectors. In some embodiments, the at least one optic is configured to align photons emitted from one sample well of the array of sample wells to overlap with a detection region of one photodetector in the array of photodetectors. In some embodiments, the at least one optic includes a dichroic mirror positioned to direct light emitted by at least one light source towards the array of sample wells and transmit light emitted by the luminescent molecule to the array of photodetectors.

In some embodiments, the system further comprises: at least one waveguide, wherein at least a portion of the sample wells in the array of sample wells are positioned to receive light from the at least one waveguide. In some embodiments, the array of sample wells and the at least one waveguide are integrated on a sample chip, the array of sample wells being arranged on a surface of the sample chip. In some embodiments, the sample chip further comprises a grating coupler configured to receive light from an external light source and optically couple light into the at least one waveguide. In some embodiments, the at least one optic includes a plurality of lenses arranged in a relay lens configuration.

In some embodiments, the array of photodetectors comprises an array of single-photon avalanche photodiodes.

Some embodiments are directed to an apparatus including detection circuitry comprising an array of photodetectors. The detection circuitry being configured to count incident photons received by the array of photodetectors from luminescent molecules to distinguish between the luminescent molecules associated with different nucleotides being incorporated into a nucleic acid molecule.

In some embodiments, the detection circuitry is further configured to generate signals identifying a series of nucleotides as individual nucleotides are incorporated into the nucleic acid molecule. In some embodiments, the luminescent molecules label different types of nucleotides.

In some embodiments, the apparatus further comprises a plurality of sample wells configured to receive a template nucleic acid molecule, wherein one photodetector in the array is positioned receive light from one of the plurality of sample wells. In some embodiments, the nucleic acid molecule is complementary to the template nucleic acid molecule.

Some embodiments are directed to a photodetection method that includes receiving, by a photodetector in an array of photodetectors, photons from a luminescent molecule, and counting, using detection circuitry, a quantity of photons incident to the photodetector during a first time period and a second time period.

In some embodiments, the photodetection method further comprises generating signals identifying the luminescent molecule, wherein the signals indicate a first quantity of photons received by the photodetector during the first time period and a second quantity of photons received by the photodetector during the second time period. In some embodiments, the photodetection method further comprises illuminating the sample with a pulse of excitation light, and wherein counting the quantity of photons occurs in response to illuminating the sample with a pulse of excitation light.

Some embodiments are directed to at least one non-transitory computer-readable storage medium storing processor-executable instructions that, when executed by at least one hardware processor, cause the at least one hardware processor to perform a photon detection method comprising: receiving, from circuitry configured to control at least one light source, a control signal corresponding to a pulse of light emitted by the at least one light source; and controlling, in response to receiving the control signal, detection circuitry configured to perform counting of photons incident to a photodetector in an array of photodetectors, wherein the counting includes counting a quantity of incident photons received by the detector during a first time period and a second time period.

In some embodiments, the detection circuitry is further configured to generate signals indicative of the quantity of incident photons received by the photodetector during the first time period and the second time period. In some embodiments, the signals generated by the detection circuitry include a first signal identifying a first quantity of incident photons received by the photodetector during the first time period and a second signal identifying a second quantity of incident photons received by the photodetector during the second time period.

Some embodiments are directed to a method for aligning an array of sample wells to an array of photodetectors, the method comprising: detecting, using the array of photodetectors, light from the array of sample wells incident to the array of photodetectors; and adjusting, based on the detected light, the positioning of the array of sample wells to the array of photodetectors to allow at least a portion of sample wells in the array of sample wells to optically align with at least a portion of the photodetectors in the array of photodetectors.

In some embodiments, an amount of light detected by individual photodetectors in the array of photodetectors indicates a degree of alignment of the array of sample wells to the array of photodetectors. In some embodiments, adjusting the positioning of the array of sample wells to the array of photodetectors includes moving the array of sample wells from a first position to a second position, wherein a first subset of the photodetectors in the array of photodetectors detect a larger amount of photons when the array of sample wells is in the second position than in the first position. In some embodiments, a second subset of the photodetectors in the array of photodetectors detect a smaller amount of photons when the array of sample wells is in the second position than in the first position.

In some embodiments, adjusting the positioning of the array of sample wells to the array of photodetectors comprises positioning at least one row of sample wells in the array of sample wells to optically align with at least one row of photodetectors in the array of photodetectors. In some embodiments, adjusting the positioning of the array of sample wells to the array of photodetectors comprises moving the array of sample wells and/or the array of photodetectors in a translational direction. In some embodiments, adjusting the positioning of the array of sample wells to the array of photodetectors comprises rotating the array of sample wells and/or the array of photodetectors at an angle. In some embodiments, adjusting the positioning of the array of sample wells to the array of photodetectors comprises comparing a pattern of the detected light to an alignment pattern, the alignment pattern having at least one of the photodetectors as detecting an amount of light below a threshold.

Some embodiments are directed to a computer readable storage medium having stored thereon instructions, which when executed by a processor, perform a photodetection method that includes receiving, from circuitry configured to control at least one light source, a control signal corresponding to a pulse of light emitted by the at least one light source, and controlling, in response to receiving the control signal, detection circuitry configured to perform counting of photons incident to a photodetector in an array of photodetectors. The counting of photons includes counting a quantity of incident photons received by the detector during a first time period and a second time period.

Some embodiments are directed to a method for aligning an array of sample wells to an array of photodetectors. The method includes detecting, using the array of photodetectors, light from the array of sample wells incident to the array of photodetectors, and adjusting, based on the detected light, the positioning of the array of sample wells to the array of photodetectors to allow at least a portion of sample wells in the array of sample wells to optically align with at least a portion of the photodetectors in the array of photodetectors.

Some embodiments are directed to a system including a stage, an array of photodetectors configured to detect light, detection circuitry associated with the array of photodetectors and configured to generate signals indicative of photons incident to the array of photodetectors, and circuitry. The circuitry is configured to perform a method that includes receiving the signals from the detection circuitry, and adjusting, based on the received signals, the positioning of the stage relative to the array of photodetectors to allow at least a portion of sample wells in the array of sample wells to optically align with at least a portion of the photodetectors in the array of photodetectors.

In some embodiments, the circuitry comprises: at least one processor; and at least one computer-readable storage medium encoded with computer-executable instructions that, when executed, perform the method.

In some embodiments, the received signals indicate an amount of light detected by individual photodetectors in the array of photodetectors, and the amount of light indicates a degree of alignment of the array of sample wells to the array of photodetectors. In some embodiments, adjusting the positioning of the stage relative to the array of photodetectors further comprises adjusting the position of the stage from a first position to a second position, wherein a first subset of the photodetectors in the array of photodetectors detect a larger amount of photons when the stage is in the second position than in the first position. In some embodiments, a second subset of the photodetectors in the array of photodetectors detect a smaller amount of photons when the array of sample wells is in the second position than in the first position. In some embodiments, adjusting the positioning of the array of sample wells to the array of photodetectors comprises positioning at least one row of sample wells in the array of sample wells to align with at least one row of photodetectors in the array of photodetectors

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a block diagram illustrating a detection system, in accordance with some embodiments of the technology described herein.

FIG. 2 is a schematic illustrating exemplary optical components, which may be included in a detection system, in accordance with some embodiments of the technology described herein.

FIG. 3 is a plot illustrating operation of electrical gates over time, in accordance with some embodiments of the technology described herein.

FIG. 4A is a schematic of exemplary types of circuits that may be included in detection circuitry, in accordance with some embodiments of the technology described herein.

FIG. 4B is a flowchart of an illustrative process for obtaining photon counts, in accordance with some embodiments of the technology described herein.

FIG. 5 is a plot of spectral photon detection efficiency for an array of single-photon avalanche photodiodes, in accordance with some embodiments of the technology described herein.

FIG. 6 is a plot of spectral photon detection efficiency for a single-photon avalanche photodiode, in accordance with some embodiments of the technology described herein.

FIG. 7 is a plot of emission probability curves for two different luminescent molecules having different emission decay characteristics, in accordance with some embodiments of the technology described herein.

FIG. 8 is a plot of photon counting of emission photons, in accordance with some embodiments of the technology described herein.

FIG. 9 is plot of a train of optical pulses, in accordance with some embodiments of the technology described herein.

FIG. 10 is a schematic of an exemplary biological reaction that may occur within a sample well, in accordance with some embodiments of the technology described herein.

FIG. 11 is a schematic of a cross-sectional view of an exemplary sample chip having a row of sample wells, in accordance with some embodiments of the technology described herein.

FIG. 12A is a planar view illustrating optical alignment of a sample well array to a photodetector array, in accordance with some embodiments of the technology described herein.

FIG. 12B is a planar view illustrating translational misalignment between a sample well array and a photodetector array, in accordance with some embodiments of the technology described herein.

FIG. 12C is a planar view illustrating rotational misalignment between a sample well array and a photodetector array, in accordance with some embodiments of the technology described herein.

FIG. 13 is a flow chart of an illustrative process for aligning a sample well array to a photodetector array, in accordance with some embodiments of the technology described herein.

FIG. 14 is a block diagram of an illustrative computing device that may be used in implementing some embodiments of the technology described herein.

### DETAILED DESCRIPTION

Aspects of the present application relate to systems and related methods for analyzing samples in parallel, including identification of single molecules within a sample and sequencing of nucleic acids. Analysis of a sample may include labeling molecules in the sample with one or more luminescent labels (e.g., fluorescent molecules), which may be used to detect the sample and/or identify single molecules of the sample (e.g., identify individual nucleotides as part of nucleic acid sequencing). A luminescent molecule, such as a molecule labeled with a fluorescent molecule or a molecule that may otherwise emit light, may become excited in response to illuminating the luminescent molecule with excitation light (e.g., light having a characteristic wavelength that may excite the luminescent molecule to an excited state) and, if the luminescent molecule becomes excited, emit emission light (e.g., light having a characteristic wavelength emitted by the luminescent molecule by returning to a ground state from an excited state). Detection of the emission light may allow for identification of the luminescent molecule using one or more characteristics of the light, including a temporal characteristic of the light it emits (e.g., its emission decay time period, or “lifetimes”), a characteristic emission wavelength, and a characteristic absorption wavelength. A temporal characteristic of light may be identified by illuminating a luminescent molecule with excitation light and determining times associated with when photons are received from the luminescent molecule by a photodetector following illumination. Typical temporal characteristics of light can range from picoseconds to hundreds of nanoseconds.

Limitations in identifying temporal characteristics of light may arise from the short time scale during which photons are emitted from a luminescent molecule upon reaching an excited state and that some photodetectors may not be able to operate in a manner that allows for detection of photons on these time scales. These limitations may become more significant in the context of single molecule detection where identification of luminescent molecules may become limited by using a single luminescent molecule or a low number of luminescent molecules to label a single molecule and the probability of the luminescent molecules to emit light in response to becoming excited. To some extent, these limitations can be overcome by performing repeated illumination of the sample and detection of emitted photons, where the photons detected during the same time period following different illumination events may be accumulated to identify a time profile characterizing emitted light from a particular sample. However, the timing associated with such repeated illumination and photon detection becomes limited in some respects by the photodetectors being used. For example, some photodetectors may only be able to detect photons received within one time period following illumination of the sample because the photodetector may lack the ability to configure itself for multiple detection time periods within the short time frame needed for detecting temporal characteristics of light, which can range from picoseconds to hundreds of nanoseconds. These types of limitations may lead to incomplete or inaccurate time profiles of the emitted light, which may result in incorrect identification of molecules as being present in the sample or an indication that a particular molecule is not present in the sample. In the context of real-time nucleic acid sequencing where the luminescent molecule being identified is used to label a nucleotide or nucleotide analog being incorporated into a complementary nucleic acid strand, further limitations may arise from the timing of the incorporation events, which can be in the range of 10 ms to 1000 ms. Some conventional photodetectors may lack the ability to perform repeated photon detection, time-synchronized to repeated illumination within this time scale and, thus, lack the ability to detect attributes (e.g., fluorescence lifetime) of individual incorporation events with a desired level of accuracy.

The inventors have recognized and appreciated that identifying photons received during multiple time periods following illumination of a sample may improve detection of a temporal characteristic of a luminescent molecule present in the sample. Aspects of the present application relate to photodetectors and associated detection circuitry configured to detect a quantity of photons received by a photodetector within multiple time periods following a reference time, which may be a time associated with a pulse of excitation light illuminating the sample. In some embodiments, the detection circuitry may count a quantity of incident photons received from a luminescent molecule at a photodetector during a first time period and a second time period following illumination of the luminescent molecule with excitation light. The detection circuitry may include at least a first photon counting circuit and a second photon counting circuit associated with the photodetector and may generate signals indicative of the quantity of incident photons received during the first time period and the second time period, respectively. A readout signal generated by the detection circuitry may include the first signal and the second signal. In this manner, the resulting readout signal from the detection circuitry may provide an indication of a temporal characteristic (e.g., lifetime) of light emitted by the luminescent molecule. In some embodiments, the photodetector is a single-photon avalanche photodiode, and the detection circuitry may perform photon counting based on electrical signals generated by the single-photon avalanche photodiode in response to receiving incident photons.

The inventors have recognized and appreciated that implementing photodetectors and associated detection circuitry configured to perform photon counting during multiple time periods as described herein may provide various benefits that improve detection of temporal characteristics of luminescent molecules. These benefits include the ability to detect a quantity of photons received during multiple time periods following a single instance of illuminating the sample. This may allow for improved identification of a time profile characterizing temporal characteristics of luminescent molecules, which may result in a more accurate detection of luminescent molecules as being present in a sample. Such photodetectors and detection circuitry as described herein may be particularly beneficial for applications that involve detecting luminescent molecules within short time scales, such as those needed for performing real-time nucleic acid sequencing. In particular, the time constraints associated with individual incorporation events can limit the duration of time allowed for detecting photons emitted by luminescent molecules used to label nucleotides or nucleotide analogs that are being incorporated into a growing nucleic acid strand. By implementing photodetectors and detection circuitry configured to perform photon counting and accumulation during multiple time periods, fewer repetitions of illumination followed by photon detection may be needed to achieve the same or similar time profile for a luminescent molecule than when using conventional photodetectors that can only detect photons within a single time period following illumination. Additionally, operating photodetectors and detection circuitry in a mode where a readout frame includes signals associated with the accumulation of photon counts over multiple repetitions of illumination may improve the signal to noise ratio, which may also reduce the illumination intensity needed to achieve a desired signal to noise ratio.

Some embodiments of the present application relate to a detection system for detecting luminescent molecules that includes photodetectors and detection circuitry configured to perform photon counting during multiple time periods as described herein. The detection system may include a sample well array, where individual sample wells in the array are configured to receive a sample (e.g., template nucleic acid molecule). The detection system may include one or more light sources configured to emit light, which may excite luminescent molecules present in the sample, and one or more optical components configured to direct light towards the sample well array. According to some embodiments, the one or more light sources may be configured to emit pulses of light and the timing of the photon counting performed by the detection circuitry may depend on the timing of the pulses of light. In particular, control circuitry associated with the one or more light sources may generate control signals corresponding to when individual pulses of light are emitted, and the detection circuitry may begin to perform photon counting in response to receiving the control signals. In this manner, the pulses of light emitted by a light source may act as an external trigger for the detection circuitry to begin to perform photon counting.

The sample well array may be integrated as part of a sample chip, which may interface with another component of the detection system, such as a stage. The stage may be used to position the sample well array relative to the photodetectors. The sample chip may be removably attached to the component, which may allow for separate sample chips to be used for different samples during operation. Accordingly, aspects of the present application are directed to techniques for aligning a sample well array to a photodetector array in a manner that allows for photons emitted from different sample wells to be distinguished from one another based on which photodetector is used to detect the emitted photons. Alignment of the sample well array to the photodetector array may involve positioning the two arrays relative to one another (e.g., adjusting the positioning of a stage for the photodetector array and/or a stage for the sample well array) such that some or all of the sample wells optically align with at least some of the photodetectors. In some embodiments, alignment of the sample well array to the photodetector array may involve positioning the two arrays relative to one another such that there is a one-to-one correspondence between individual sample wells and individual photodetectors.

The inventors have further recognized and appreciated that configuring the sample well array and the photodetector array such that not all photodetectors are optically aligned to sample wells may provide certain benefits during the alignment process. In particular, the arrangement of photodetectors in the photodetector array and the arrangement of sample wells in the sample well array may be such that when some sample wells are in optical alignment with photodetectors, there are some photodetectors not optically aligned with sample wells. In such cases, techniques for aligning the sample well array to the photodetector array may involve adjusting the relative positioning of the two arrays based on signals indicative of the amount of light being detected by the photodetectors such that one subset of the photodetectors detect a larger amount of photons in a subsequent position while another subset of photodetectors detect a smaller amount of photons in the subsequent position. In this manner, some photodetectors may be designated as photodetectors positioned to receive light, which may be referred to as “bright” photodetectors, while other photodetectors may be designated as photodetectors positioned to not receive light, which may be referred to as “dark” photodetectors because they detect no photons or a small amount of photons when in alignment. For example, the positioning of rows and/or columns of the sample wells in the sample well array and the positioning of rows and/or columns of the photodetectors in the photodetector array may be such that when some rows or columns of photodetectors are in optically alignment with sample wells there are other rows or columns of photodetectors that are not. In such cases, a process for aligning the sample well array to the photodetector array may involve adjusting the position of the array of sample wells to the array of photodetectors such that some rows or columns of photodetectors detect a higher amount of photons while other rows or columns of photodetectors detect a smaller amount of photons. These alignment techniques may overcome certain difficulties in optically aligning a sample well array to a photodetector array. For example, designating some photodetectors as “dark” may facilitate more fine adjustments because detecting lack of an optical signal or a smaller optical signal may be easier than detecting when an optical signal increases. These optical alignment techniques may be particularly suited when the number of sample wells is large, such as when the number of sample wells is in the range of 100 and 100,000.

The aspects and embodiments described above, as well as additional aspects and embodiments, are described further below. These aspects and/or embodiments may be used individually, all together, or in any combination of two or more, as the application is not limited in this respect.

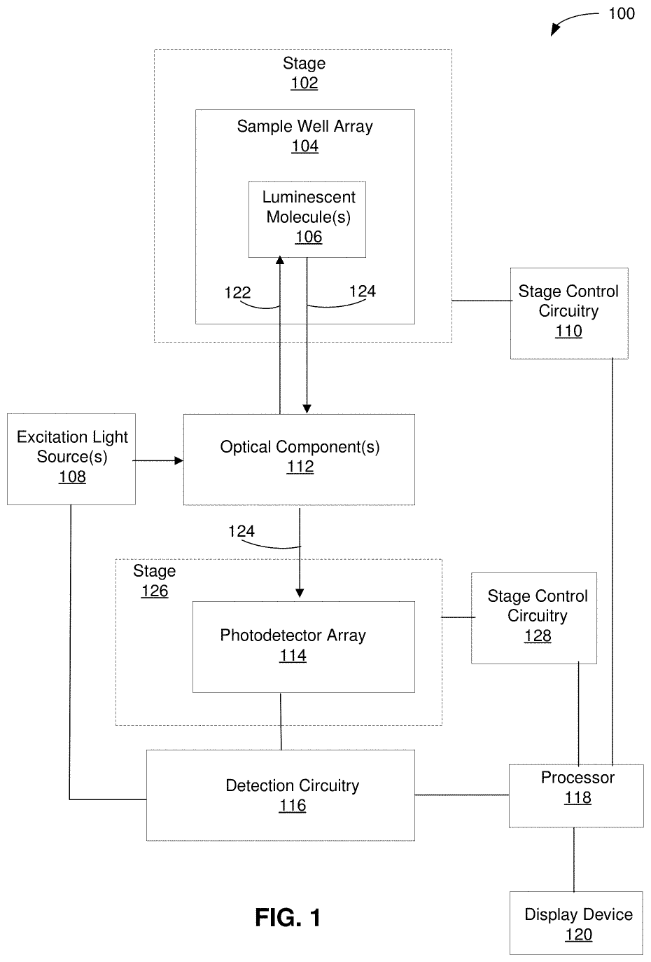

FIG. 1 is a block diagram illustrating molecule detection system 100, which may detect luminescent molecules present in a sample according to some embodiments. Detection system 100 may include sample well array 104 having sample wells configured to receive molecules, including molecules of a sample (e.g., template nucleic acid) and luminescent molecules 106 (e.g., fluorescently labeled nucleotides). Detection system 100 may include excitation light source(s) 108, which emit light 122 that may excite luminescent molecule(s) 106. When a luminescent molecule is positioned within a sample well of array 104 and receives light 122, the luminescent molecule may emit emission light 124 in response. Detection system 100 may include photodetector array 114 configured to detect light 124 from sample well array 104, including light 124 emitted by luminescent molecule(s) 106. Individual photodetectors in array 114 may correspond to a sample well in array 104 such that light detected by a particular photodetector is identified as originating from a particular sample well. Detection system 100 may include detection circuitry 116, which may detect signals generated by photodetectors in photodetector array 114, where the signals indicate incident photons detected by the photodetectors. In some embodiments, a photodetector may generate a current corresponding to an incident photon received by the photodetector, and detection circuitry 116 may detect the current. In this manner, photodetector array 114 and detection circuitry 116 may allow for detection of single photons and for counting of individual photons. In some embodiments, photodetector array 114 includes single-photon avalanche diodes (SPADs). In such embodiments, a SPAD may generate a charge carrier in response to receiving an incident photon, which may trigger an avalanche current having a duration of time. Detection circuitry 116 may detect the avalanche current, and generate a signal indicating that the SPAD received an incident photon.

In some embodiments, the arrangement of photodetectors in photodetector array 114 may include positioning of the photodetectors such that the photodetectors are spaced apart from one another by a particular distance, which may be in the range of 50 μm to 600 ∥m, or any value or range of values in that range. In some embodiments, the arrangement of photodetectors in array 114 may be such that the photodetectors are spaced apart from one another by a distance that is at least 500 μm. These types of photodetector arrangements may improve the ability of the detection system to detect single molecules because the individual photodetectors can be positioned to receive light emitted from a particular region or location. In such cases, the photodetector array may have a detector area to imaging area percentage equal to less than 10%. In some embodiments, the detector area to imaging area percentage may be in the range of 1% to 5%. Individual photodetectors in array 114 may have an active diameter in the range of 10 μm to 50 μm, or any value or range of values in that range. In the context of using the integrated device described herein for single molecule analysis, these photodetector arrangements may improve detection of light emitted from a single sample well by the individual photodetectors in the array 114.

It should be appreciated that these types of photodetector arrangements may be suitable for other light detection and imaging techniques that involve detection of light from a particular region. In the context of imaging techniques, having an arrangement of photodetectors with a suitably low detector area to imaging area, which may also be referred to as having a low fill factor, may allow for the individual photodetectors to act as an array of apertures capable of detecting light originating from particular regions within a sample. In particular, such photodetector arrangements may be implemented to achieve improved optical resolution of a sample being imaged because of the positioning of the photodetectors to detect light originating from the sample at a particular region. For example, such photodetector arrangements may provide benefits for particular types of imaging techniques that involve scanning areas of a sample, such as confocal microscopy. In conventional confocal microscopy, optical resolution of the sample being imaged can be achieved by using point illumination to illuminate one section in the sample at a time and scanning the point illumination over a particular region of the sample to obtain an image of the region of the sample, which may be referred to as a raster scan. In contrast, an arrangement of photodetectors having a low fill factor may be implemented to provide a desired optical resolution in an image of a sample without having to perform a complete scan as in conventional confocal microscopy because the individual photodetectors correspond to particular, discernable sections of the sample being imaged. Instead of scanning the entire region of the sample to form an image, either the sample plane or the photodetector array may be moved such that the individual photodetectors are used to scan particular sections within a region of the sample to form a complete image of the region. Such techniques may improve the speed in which an image having a similar optical resolution as a confocal image is obtained because image data is acquired by some or all of the photodetectors during each repositioning of the photodetector array and the sample relative to each other such that smaller sections of the sample are effectively scanned. Those scanned smaller sections can then be combined to form a complete image of the region of interest in the sample. It should be appreciated that these imaging techniques may be applied to different types of sample illumination including, total internal reflection fluorescence (TIRF) illumination, incoherent wide field illumination, illumination by a laser spot array, or any other structured sample illumination techniques.

Any suitable optical coupling techniques may be implemented to couple light emitted by excitation light source(s) 108 to sample well array 104 such that some or all of the sample wells in array 104 receive the light. In some embodiments, a beam of light emitted by excitation light source(s) 108 may illuminate some or all of sample wells in array 104. In embodiments where a beam of light is directed towards a side of array 104, such positioning of excitation light source(s) 108 to sample well array 104 may be considered as backside illumination. In some instances, one or more optical components positioned relative to excitation light source(s) 108 and sample well array 104 may act to spread the diameter of the beam of light emitted by excitation light source(s) 108 in a manner that allows for multiple sample wells in the array to receive light 122. In other embodiments, sample well array 104 is integrated as part of a photonic device, which may be referred to as a “sample chip.” The sample chip may include one or more waveguides configured to propagate the light to the sample wells. The one or more waveguides may optically couple to excitation light source(s) 108 through any suitable coupling component, including a facet optical coupler and a grating optical coupler.

Detection system 100 may include optical component(s) 112, which may include any suitable optics for directing light emitted from sample well array 104 towards photodetector array 114. In some embodiments, optical component(s) 112 may be positioned to direct photons emitted from one sample well in sample well array 104 to one photodetector in photodetector array 114. As an example, optical component(s) 112 may direct light from individual sample wells to their corresponding photodetectors such that light emitted from the sample well is detected only by its corresponding photodetector. In such cases, optical component(s) 112 positioned in detection system 100 may align photons emitted from one sample well of sample well array 104 to optically overlap with a detection region of a photodetector in photodetector array 114 such that some or all of the emitted photons are incident to the detection region.

Optical component(s) 112 may include one or more optics for directing excitation light 122 emitted by excitation light source(s) 108 towards sample well array 104 such that excitation light optically couples with sample well array 104. Some combination of optical component(s) 112 (which may include, for example, none, one, or more of each of: lens, mirror, optical filter, attenuator, beam-steering component, beam shaping component) and be configured to operate on and/or deliver light from an excitation light source to sample well array 104. Optical component(s) 112 may be arranged to direct light to at least one sample well, which may include a sample to be analyzed, and direct optical signals (e.g., fluorescence, backscattered radiation) from the at least one sample well towards photodetector array 114, where detection circuitry 116 may produce one or more electrical signals representative of the received optical signals. In some embodiments, optical component(s) 112 may include a dichroic mirror positioned to direct light emitted by excitation light source(s) towards sample well array 104. The dichroic mirror may allow for light emitted by luminescent molecule(s) 106 to transmit through the dichroic mirror to photodetector array 114 while reducing transmission of excitation light towards photodetector array 114. In some embodiments, optical component(s) 112 may include multiple lenses arranged in a relay lens configuration. The relay lens configuration may allow for a one-to-one correspondence between individual sample wells in array 104 and individual photodetectors in photodetector array 114.

Detection system 100 may include stage(s) with associated stage control circuitry for positioning sample well array 104 and photodetector array 114 relative to one another. The stage(s) may be configured to provide translational and/or rotational degrees of freedom when moving sample well array 104 and/or photodetector array 114. For example, sample well array 104 may be mounted onto stage 102 and photodetector array 114 may be mounted on stage 126. As shown in FIG. 1, detection system 100 may include stage 122 for positioning sample well array 104 and stage 126 for positioning photodetector array 114. Stage control circuitry 110 coupled to stage 122 may provide control signals for controlling stage 122, while stage control circuitry 128 coupled to stage 126 may provide control signals for controlling stage 126. Stages 102 and/or stage 126 may be configured to provide translational and/or rotational motion for sample well array 104 and/or photodetector array 114. For example, stage 102 may be configured to provide translational motion for sample well array 104 while stage 126 may be configured to provide rotational motion for photodetector array 114. In yet another example, stage 102 may be configured to provide rotational motion for sample well array 104 while stage 126 may be configured to provide translational motion for photodetector array 114. In yet another embodiments, both stage 102 and stage 126 may be configured to provide both rotational and translational motion.

Although stages 102 and 126 and associated control circuitry 110 and 128 are shown in FIG. 1, it should be appreciated that some embodiments of the detection system described herein may involve using only one stage, such as a stage for moving sample well array 104 or a stage for moving photodetector array 114. In such embodiments, the stage may be configured to provide both rotational and translational motion for positioning sample well array 104 relative to photodetector array 114. For example, in some embodiments of the detection system described herein, stage 102 may be configured to provide both translational and rotational motion for sample well array 104. As another example, stage 126 may be configured to provide both translational and rotational motion for photodetector array 114.

In some embodiments, some or all of optical component(s) 112 may be mounted to one or more stages of the detection system, such as on stage 102 or on stage 126 as shown in FIG. 1. In some embodiments, excitation light source(s) 108 may be mounted to one of the stages of the detection system, such as on stage 102. Mounting some or all of the optical component(s) 112 and/or excitation light source(s) 108 on a stage may reduce the need to realign the excitation light to the sample well array 104 during positioning of sample well array 104 relative to photodetector array 114, which may allow for improved optical alignment of sample well array 104 relative to excitation light source(s).

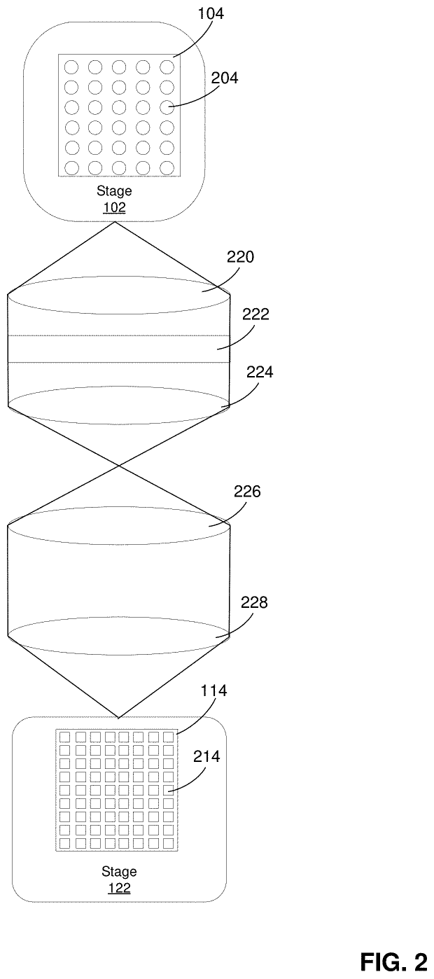

FIG. 2 is a schematic of exemplary optical components 220, 222, 224, 226, and 228 that may be used in detection system 100 to direct emission light from sample wells 204 of sample well array 104 to photodetectors 214 in photodetector array 114, according to some embodiments. As shown in FIG. 2, optical components include lens 220, filter 222, lens 224, lens 226, and lens 228. In some embodiments, lens 220 is a 60x objective. In some embodiments, lens 224 is a lx tube lens. In some embodiments, lens 226 is a relay lens having a focal length of 100 mm. In some embodiments, lens 228 is a relay lens having a focal length of 200 mm. Filter 222 may be configured to reduce or block transmission of excitation light, which may reduce excitation light from reaching photodetectors 214 in photodetector array 114.

Detection circuitry 116 associated with photodetector array 114 is configured to perform photon counting of photons incident to individual photodetectors. In some embodiments, detection circuitry 116 may include signal-processing electronics (e.g., one or more microcontrollers, one or more field-programmable gate arrays, one or more microprocessors, one or more digital signal processors, logic gates, etc.) configured to process the electrical signals from the photodetectors. During operation when photodetector array 114 is positioned to receive photons emitted from luminescent molecule(s) 106, detection circuitry 116 may generate signals identifying individual luminescent molecules. The signals generated by detection circuitry 116 may allow for distinguishing among different types of luminescent molecules. Detection circuitry 116 may generate a first signal identifying a first type of luminescent molecule and a second signal identifying a second type of luminescent molecule.

In some embodiments, detection circuitry 116 may count a quantity of photons incident to a photodetector in photodetector array 114 during different time periods following a reference time. The reference time may act as a trigger for detection circuitry 116 to begin counting photons that are incident to a photodetector in array 114. Detection circuitry 116 may receive control signals indicating the reference time from an external device and, in response to receiving the control signals, detection circuitry 116 may begin performing photon counting of photons incident to photodetectors in array 114. In some embodiments, detection circuitry 116 is configured to count a quantity of photons incident at a photodetector during a first time period and a second time period following a reference time. The first time period and the second time period may be non-overlapping time periods. In some embodiments, a period of time where incident photons are not being counted by detection circuitry 116 may separate the first time period and the second time period. Such a time period, which may be considered as a “delay time,” may allow for rearming of the detection circuitry between the first and second time periods and may improve accuracy of photon counting by the detection circuitry.

In some embodiments, detection circuitry 116 may include multiple photon counting circuits for counting photons incident to photodetectors in photodetector array 114. In such embodiments, detection circuitry 116 may include one or more photon counting circuits associated with individual photodetectors in photodetector array 114 where each of the photon counting circuit(s) is configured to count a quantity of incident photons received by its corresponding photodetector during a time period. When multiple photon counting circuits are associated with a photodetector in photodetector array, then each of the photon counting circuits may correspond to a different time period during which photons incident to the photodetector are counted. In some embodiments, two or more photon counting circuits are associated with individual photodetectors in photodetector array 114 and are configured to generate signals indicative of the quantity of incident photons received by a photodetector during two or more time periods. As an example, individual photodetectors in photodetector array 114 may have two photon counting circuits, which are configured to generate signals indicative of a quantity of photons incident to a photodetector during a first time period and a second time period following a reference time. The signals generated by the photon counting circuits may include a first signal identifying a first quantity of incident photons received by the photodetector during the first time period and a second signal identifying a second quantity of incident photons received by the photodetector during the second time period. The two photon counting circuits may individually generate one of the first and second signals such that a first photon counting circuit performs photon counting during the first time period and generates the first signal, and a second photon counting circuit performs photon counting during the second time period and generates the second signal. In such embodiments, detection circuitry 116 may generate a readout signal that includes the first signal and the second signal.

The reference time that triggers when detection circuitry 116 begins to perform photon counting may correspond to a time associated with illuminating sample well array 104 with excitation light. Such a reference time may allow detection circuitry 116 to begin counting photons emitted by luminescent molecule(s) 106 that became excited by being illuminated with the excitation light. Signals generated by detection circuitry 116 may provide an indication of the emission lifetime of the luminescent molecule(s). Detection circuitry 116 may receive periodic control signals indicating multiple reference times, and detection circuitry 116 may perform photon counting following each of the individual reference times. In this manner, detection circuitry 116 may perform repeated photon counting following illumination of luminescent molecule(s), which may improve detection of the luminescent molecule(s) by system 100. In some embodiments, excitation light source(s) 108 emit pulses of light and the reference time corresponds to a time associated with excitation light source(s) 108 emitting a pulse of light. In such embodiments, circuitry associated with excitation light source(s) 108 may generate control signals corresponding to the emitted light pulses. The control signals may be transmitted to detection circuitry 116 and used as a series of reference times to trigger when detection circuitry 116 performs photon counting.

According to some embodiments, detection circuitry 116 may perform photon counting by generating electrical signals at times associated with the photon counting time periods to control whether individual photons detected by the photodetectors are counted by detection circuitry 116. These electrical signals may act as an electrical gate such that when the electrical gate is in an OFF state the detection circuitry performs photon counting and when the electrical gate is in an ON state the detection circuitry does not perform photon counting. In embodiments where the photodetectors are single-photon avalanche photodiodes, which generate current in response to receiving incident photons, the electrical signals generated by detection circuitry 116 may control whether the detection circuitry 116 receives the current generated by a single-photon avalanche photodiodes. In performing photon counting over multiple time periods, detection circuitry 116 may operate the electrical gate such that the electrical gate is OFF during times associated with the individual time periods and ON during times outside of the time periods. In this manner, detection circuitry 116 may control the timing of when photon counting occurs. In some embodiments, detection circuitry 116 may be configured to operate multiple electrical gates. In such instances, detection circuitry 116 may have an electrical gate corresponding to each photon counting circuit associated with a photodetector, where the electrical gate for a particular photon counting circuit is configured to control the timing associated with when the photon counting circuit performs photon counting.

The electrical gate may depend on the timing of a reference signal, which may be external to the detection circuitry, such that the timing of the ON and OFF states of the electrical gate may begin in response to detection circuitry 116 receiving the reference signal. The timing of the electrical gate may depend on times associated with pulses of light emitted by excitation light source(s) 108. As discussed herein, the excitation light source(s) 108 may generate control signals corresponding to times of the pulses of emitted light and detection circuitry 116 may operate the electrical gate to perform photon counting in response to receiving the control signals.

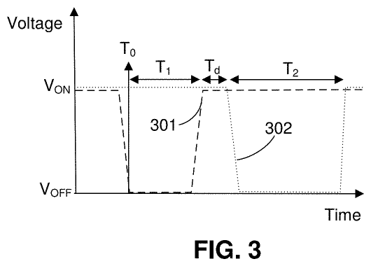

FIG. 3 is an exemplary plot illustrating how detection circuitry 116 may operate electrical gate 301 and electrical gate 302 over time. As shown in FIG. 3, the electrical gates 301 and 302 are voltage signals that are maintained at a particular voltage, V_{ON}, when the electrical gates are in an ON state to prevent detection circuitry 116 from performing photon counting. When electrical gates 301 and 302 are set to another voltage, V_{OFF}, the electrical gates are in an OFF state, and detection circuitry 116 may perform photon counting. The timing of when electrical gates are set to the OFF state occur after a reference time, T₀, which may in some embodiments be a time associated with a pulse of light emitted by excitation light source(s) 108. As shown in FIG. 3, electrical gate 301 is lowered to voltage V_{OFF} for time period T₁ following T₀. Additionally, electrical gate 302 is lowered to voltage V_{OFF} for time period T₂ subsequent time period T₁. Photon counting may be performed by detection circuitry during both time periods T₁ and T₂. For example, electrical gate 301 may correspond to an electrical gate for a first photon counting circuit, which may perform photon counting during time period T₁ and electrical gate 302 may correspond to an electrical gate for a second photon counting circuit, which may perform photon counting during time period T₂. Although time period T₁ is shown as being shorter than time period T₂ in FIG. 3, it should be appreciated that some embodiments may involve time period T₁ being longer than or the same as time period T₂. As shown in FIG. 3, there may be a delay time, T_{d}, between time period T₁ and time period T₂. Delay time, T_{d}, may be a time associated with allowing the photodetector to rearm, which may improve detection of photons during time period T₂. Time period T₁ and time period T₂ may be in the range of 1.5 ns to 20 ns, or any value or range of values in that range. Delay time, T_{d}, may be in the range 0.5 ns to 10 ns, or any value or range of values in that range. Although two time periods are shown in FIG. 3, it should be appreciate that detection circuitry may operate more than two electrical gates, depending on the number of time periods being used to perform photon counting.

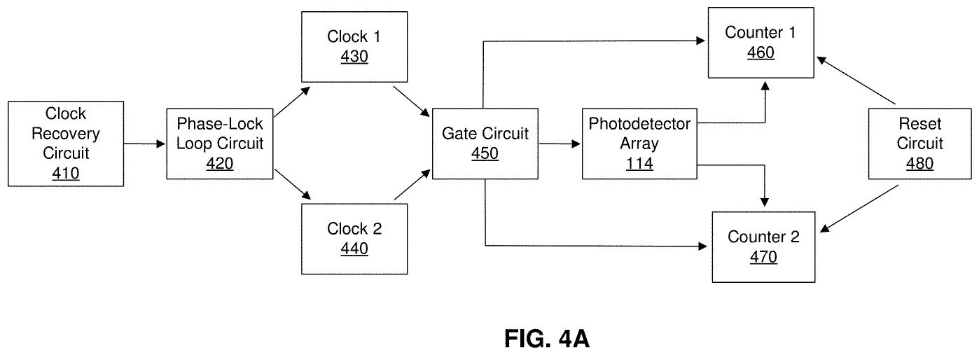

FIG. 4A is an exemplary schematic of the types of circuits that may be included in detection circuitry 116, according to some embodiments. As shown in FIG. 4A, detection circuitry may include clock recovery circuit 410, phase-lock loop circuit 420, clock 1 430, clock 2 440, gate circuit 450, counter 1 460, counter 2 470, and reset circuit 480. Clock recovery circuit 410 may receive a control signal from an external device, such as an excitation light source (e.g., a mode-locked laser), and may transmit a signal to phase-lock loop circuit 420, which may set the time periods during which photon counting is performed. Phase-lock loop circuit 420 may transmit control signals to clock 1 430 and clock 2 440. In embodiments where phase-lock loop 420 is common to both clock 1 430 and clock 2 440, clock 1 430 and clock 2 440 may have a user-programmed phase delay between clock 1 430 and clock 2 440. Clock 1 430 and clock 2 440 may control the timing of gate circuit 450 in operating an electrical gate. In particular, gate circuit 450 may control photodetector array 114 to operate in a gated mode with the timing of clock 1 430 and clock 2 440 setting the timing of the gate operation controlled by gate circuit 450. Photodetector array 114 may transmit signals indicating detection of photons by photodetector array 114 to counter 1 460 and counter 2 470, which may perform photon counting. The timing set by clock 1 430 and clock 2 440 may control the time periods during which counter 1 460 and counter 2 470 perform photon counting. Readout signals indicating photon counts may be obtained from counter 1 460 and counter 2 470. Reset circuit 480 may act to reset counter 1 460 and counter 2 470 such that counter 1 460 and counter 2 470 are in a state to perform photon counting.

The timing of photon counting performed by counter 1 460 and counter 2 470 may be set by gate circuit 450 transmitting control signals to counter 1 460 and counter 2 470 where the timing of the control signals transmitted by gate circuit 450 is determined by the timing of clock 1 430 and clock 2 440. For example, clock 1 430 may set a first time period and gate circuit 450 may control counter 1 460 to perform photon counting during the first time period, and clock 2 440 may set a second time period and gate circuit 450 may control counter 2 470 to perform photon counting during the second time period. It should be appreciated that additional clock and counter circuitry may be included to perform photon counting during more than two time periods.

FIG. 4B shows a flowchart of an illustrative process 490 for obtaining photon counts, in accordance with some embodiments of the technology described herein. Process 490 may be performed at least partially by detection circuitry 116.

Process 490 begins at act 491, where photon counting may be initiated by a trigger event. A trigger event may be an event that serves as a time reference for performing photon counting. The trigger event may be an optical pulse, such as an optical pulse generated by excitation light source(s) 108, or an electrical pulse, such as an electrical pulse generated at a time following an optical pulse. The trigger event may be a singular event or a repeating, periodic event. In the context of fluorescence lifetime measurements, the trigger event may be the generation of a light excitation pulse to excite one or more fluorophores. Photons that reach the photodetector array 114 may produce charge carriers and detection circuitry 116 may perform photon counting of the photogenerated charge carriers.

Process 490 proceeds to act 492 where clock 1 controls operation of a gate, such as clock 1 430 controlling gate circuit 450 as shown in FIG. 4A. Clock 1 may set a first period of time during which the gate is in an OFF state such that some or all of the photodetectors in photodetector array 114 may generate a signal in response to receiving photons during the first period of time. Next, process 490 proceeds to act 493 where counter 1 performs photon counting during the first period of time such that photons detected by a photodetector in array 114 during the first period of time are counted by counter 1. Some embodiments may include a counter 1 for individual photodetectors in array 114 such that photons detected by different photodetectors are counted separately by different counters during the first period of time. In some embodiments, the gate may reach an ON state after the first period of time has passed, such as by clock 1 transmitting a signal to gate circuit 450 at the end of the first period of time to set the electrical signal to an ON state.

Process 490 proceeds to act 494 where clock 2 controls operation of the gate, such as clock 2 440 controlling gate circuit 450 as shown in FIG. 4A. Clock 2 may set a second period of time during which the gate is in an OFF state such that some or all of the photodetectors in photodetector array 114 may generate a signal in response to receiving photons during the second period of time. Next, process 490 proceeds to act 495 where counter 2 performs photon counting during the second period of time such that photons detected by a photodetector in array 114 during the second period of time are counted by counter 2. As discussed above in connection with counter 1, some embodiments may include a counter 2 for individual photodetectors in array 114 such that the photons detected by different photodetectors are counted separately by different counters during the second period of time. In some embodiments, the gate may reach an ON state after the second period of time has passed, such as by clock 2 transmitting a signal to gate circuit 450 at the end of the second period of time.

Some embodiments may involve repeating this process for multiple times to obtain statistical information regarding the time periods at which photons arrive after a trigger event. Photon counts obtained by counter 1 and counter 2 may be aggregated over multiple trigger events to generate photon count signals representing a total number of photons detected during the first period of time and the second period of time over multiple trigger events. Repeating the measurement may enable aggregating photon counts to provide statistically meaningful results. For example, in the context of fluorescence lifetime measurement, it may be expected that a photon detection event in response to a photon received from a fluorophore may occur relatively rarely, such as once in about 1,000 excitation events.

Once the number of repetitions of trigger events has been performed, process 490 may proceed to act 496 of reading out the photon counts from counter 1 and counter 2. Embodiments where there are separate counters for individual photodetectors, reading out the photon counts may include reading out the photon counts for both counter 1 and counter 2 associated with different photodetectors such that a first photon count associated with counter 1 and a second photon count associated with counter 2 is obtained for individual photodetectors.

In some embodiments, once the photon counts have been read, process 490 may proceed to act 497 where counter 1 and counter 2 may be reset to a state to allow for subsequent photon counting to be performed by counter 1 and counter 2, such as following a subsequent trigger event. Act 497 may be performed by reset circuit 480 shown in FIG. 4A, according to some embodiments. Some embodiments may involve performing a reset of counters 1 and 2 following each trigger event such that photon counts for both the first period of time and the second period of time are obtained for individual trigger events.

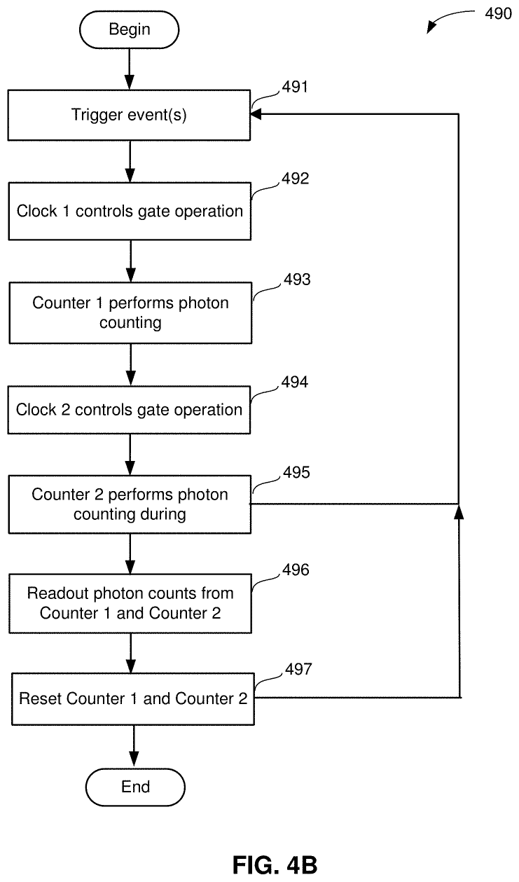

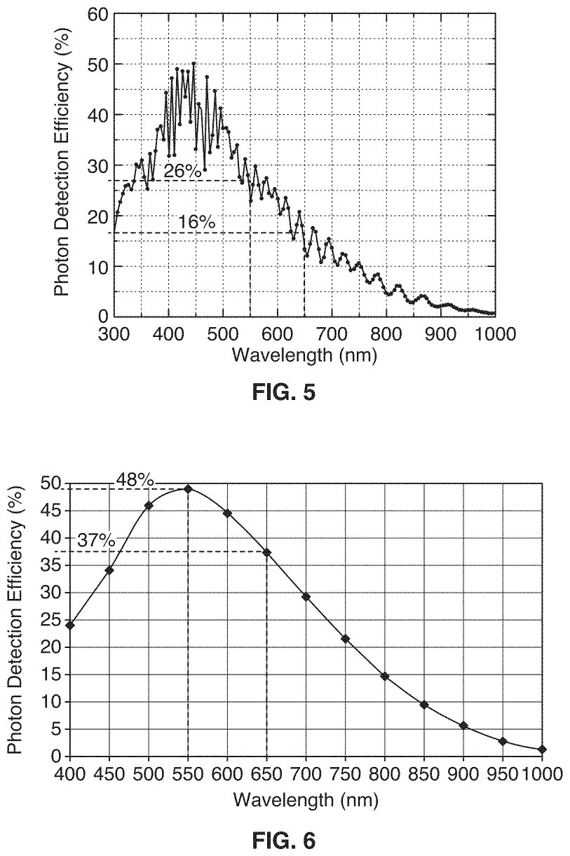

As discussed herein, the photodetectors in photodetector array 114 may include single-photon avalanche photodiodes (SPADs). The SPADs may have a desired photon detection efficiency within a spectral range between 550 nm and 650 nm, which may correspond to light emitted by luminescent molecule(s) 106. In some embodiments, SPADs may have a photon detection efficiency in the range of 15% to 50%, or any percentage or range of percentages in that range for wavelengths between 550 nm and 650 nm. FIG. 5 is a plot of spectral photon detection efficiency for an array of SPADs, which may be used as photodetectors in photodetector array 114 according to some embodiments. As shown in FIG. 5, the array of SPADs has a photon detection efficiency in the range of 16% to 26% within the range of wavelengths between 550 nm and 650 nm. FIG. 6 is a plot of spectral photon detection efficiency for a SPAD, which may be used as a photodetector in photodetector array 114 according to some embodiments. As shown in FIG. 6, the SPAD has a photon detection efficiency in the range of 37% to 48% within the range of wavelengths between 550 nm and 650 nm.

Although aspects of the technology are described in connection with SPADs, it should be appreciated that photodetector array 114 may include other types of photodetectors configured to gate with a desired timing while having a signal to noise ratio that allows for detection of individual photons. As an example, photodetectors having low dark current and low read noise operation, while exhibiting high photon sensitivity may be implemented in the technology described herein. Examples of suitable photodetectors that may be implemented in photodetector array may include complementary metal-oxide semiconductor (CMOS) photodetectors as part of a CMOS image sensor (CIS), avalanche photodiodes (APDs), and photodetectors that combine aspects of CMOS photodetectors and APDs, for example by implementing gain amplifying features to achieve a CMOS photodetector with a higher sensitivity. One benefit of CMOS photodetectors is that CMOS processing may allow for fabrication of a photodetector array having a high density of photodetectors. Some embodiments may include photodetector array 114 that has back-illuminated photodetectors, which may improve the effective quantum efficiency of the photodetectors.

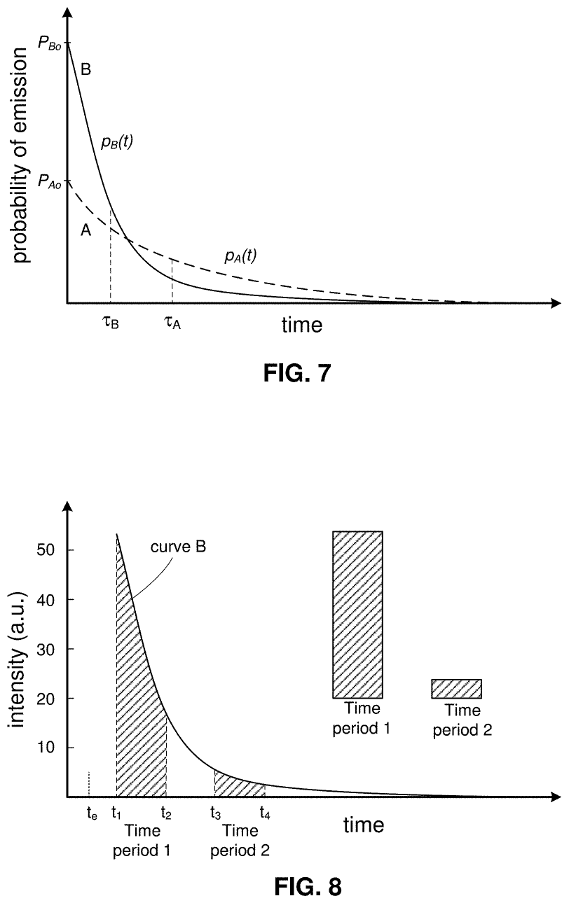

According to some embodiments, a detection system, such as detection system 100, configured to analyze samples based on emission characteristics may detect differences in lifetimes and/or intensities between different luminescent molecules. By way of explanation, FIG. 7 plots two different emission probability curves (A and B), which may be representative of emission from two different luminescent molecules. With reference to curve A (shown as the dashed line), after being excited by a short or ultrashort optical pulse, a probability p_{A}(t) of an emission from a first molecule may decay with time, as depicted. In some cases, the decrease in the probability of a photon being emitted over time may be represented by an exponential decay function p_{A}(t)=P_{Ao}e^{-t/τ}^{_{A}}, where P_{Ao} is an initial emission probability and τ_{A} is a temporal parameter associated with the first molecule that characterizes the emission decay probability. τ_{A} may be referred to as the “emission lifetime” or “lifetime” of the first luminescent molecule. Other luminescent molecules may have different emission characteristics than that shown in curve A. For example, another luminescent molecule may have a decay profile that differs from a single exponential decay, and its lifetime may be characterized by a half-life value or some other metric.

A second luminescent molecule may have a decay profile that is exponential, but has a measurably different lifetime. In FIG. 7, a luminescent molecule having the emission probability of curve B may have the exponential decay function p_{B}(t)=P_{Bo}e^{-t/τ}^{_{B}}, where P_{Bo} is an initial emission probability and τ_{B} is a temporal parameter associated with the second luminescent molecule that characterizes the emission decay probability. In the example shown, the lifetime for the second luminescent molecule of curve B is shorter than the lifetime for the first luminescent molecule of curve A, and the probability of emission is higher sooner after excitation of the second luminescent molecule represented by curve B than for the first luminescent molecule represented by curve A. Different luminescent molecules may have lifetimes or half-life values ranging from about 0.1 ns to about 20 ns, in some embodiments.

Identifying luminescent molecules based on lifetime (rather than emission wavelength, for example) can simplify aspects of a detection system. As an example, wavelength-discriminating optics (such as wavelength filters, dedicated detectors for each wavelength, dedicated pulsed optical sources at different wavelengths, and/or diffractive optics) may be reduced in number or eliminated when identifying luminescent molecules based on lifetime. In some cases, a single pulsed optical source operating at a single characteristic wavelength may be used to excite different luminescent molecules that emit within a same wavelength region of the optical spectrum but have measurably different lifetimes. A detection system that uses a single pulsed optical source, rather than multiple optical sources operating at different wavelengths, to excite and discern different luminescent molecules emitting in a same wavelength region can be less complex to operate and maintain, more compact, and may be manufactured at lower cost.

Although detection systems based on lifetime analysis may have certain benefits, the amount of information obtained by a detection system and/or detection accuracy may be increased by allowing for additional detection techniques. For example, some detection systems may additionally be configured to discern one or more properties of a sample based on emission wavelength and/or emission intensity.

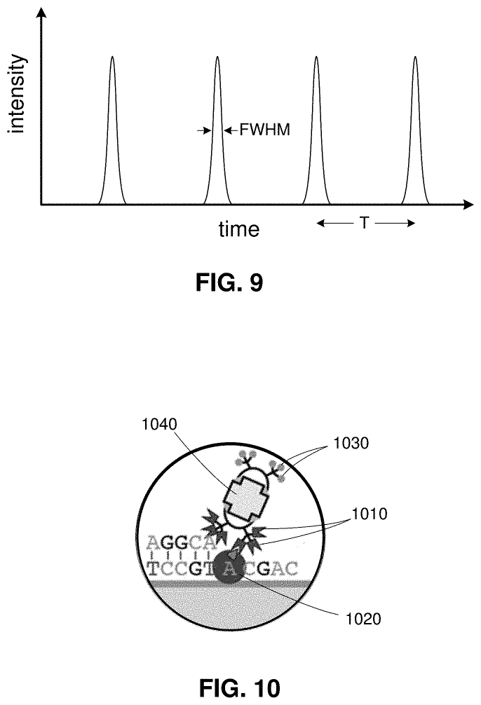

Referring again to FIG. 7, according to some embodiments, different emission lifetimes may be distinguished with a photodetector and associated detection circuitry that is configured to perform photon counting of photons incident to the photodetector following excitation of a luminescent molecule. The photon counting may occur during a single interval between read-out events during which the detection circuitry counts a quantity of photons received during multiple time periods. The concept of determining emission lifetime by photon counting is introduced graphically in FIG. 8. At time t₀ just prior to t₁, a luminescent molecule is excited by a short or ultrashort optical pulse. Detection circuitry associated with a photodetector that detects photons emitted by the luminescent molecule may count photons during multiple time periods, such as time period 1 between t₁ and t₂ and time period 2 between t₃ and t₄ indicated in FIG. 8, that are temporally resolved with respect to the excitation time of the luminescent molecule(s). By summing over multiple excitation events, the quantity of photons in each time period may approximate the decaying intensity curve shown in FIG. 8, and can be used to distinguish between different luminescent molecules.

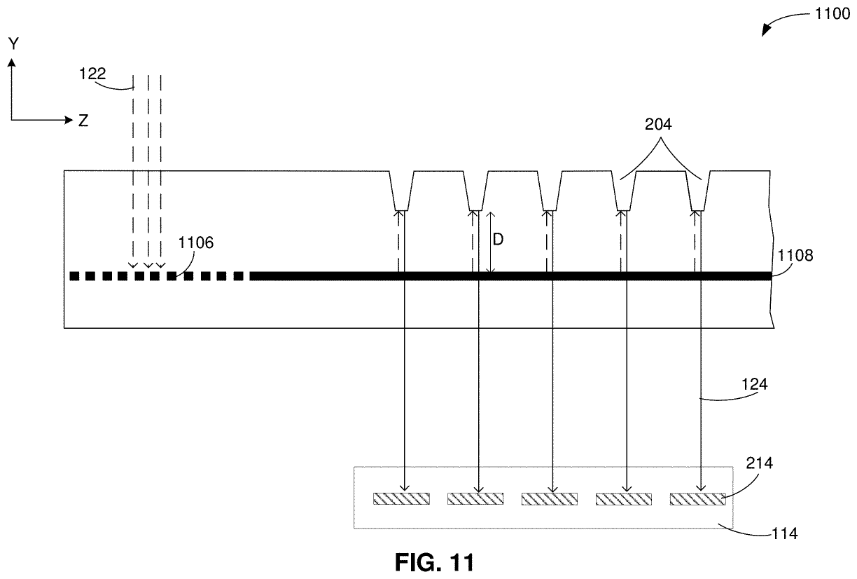

According to some embodiments, excitation light source(s) 108 in detection system 100 may comprise one or more mode-locked laser modules configured to produce pulses of excitation light. FIG. 9 depicts temporal intensity profiles of the output pulses from an exemplary mode-locked laser module. In some embodiments, the peak intensity values of the emitted pulses may be approximately equal, and the profiles may have a Gaussian temporal profile, though other profiles such as a sech² profile may be possible. In some cases, the pulses may not have symmetric temporal profiles and may have other temporal shapes. The duration of each pulse may be characterized by a full-width-half-maximum (FWHM) value, as indicated in FIG. 9. According to some embodiments of a mode-locked laser, ultrashort optical pulses may have FWHM values less than 100 picoseconds (ps). In some cases, the FWHM values may be between approximately 5 ps and approximately 30 ps.

In some embodiments, excitation light source(s) 108 may include one or more gain switched laser modules configured to produce pulses of excitation light. Examples of suitable gain switched laser modules are described in U.S. patent application Ser. No. 16/043,651, filed Jul. 24, 2018, titled “HAND-HELD, MASSIVELY-PARALLEL, BIO-OPTOELECTRONIC INSTRUMENT,” which is incorporated by reference in its entirety.

The output pulses may be separated by regular intervals T. For example, T may be determined by a round-trip travel time between an output coupler and a cavity end mirror of the laser module. According to some embodiments, the pulse-separation interval T may be in the range of approximately 1 ns to approximately 30 ns, or any value or range of values within that range. In some cases, the pulse-separation interval T may be in the range of approximately 5 ns to approximately 20 ns, corresponding to a laser-cavity length (an approximate length of an optical axis within a laser cavity of laser module) between about 0.7 meter and about 3 meters.

According to some embodiments, a desired pulse-separation interval T and laser-cavity length may be determined by a combination of the number of sample wells, emission characteristics, and the speed of data-handling circuitry for reading data from detection circuitry 116. The inventors have recognized and appreciated that different luminescent molecules may be distinguished by their different emission decay rates or characteristic lifetimes. Accordingly, there needs to be a sufficient pulse-separation interval T to collect adequate statistics for the selected luminescent molecules to distinguish between their different decay rates. Additionally, if the pulse-separation interval T is too short, the data handling circuitry may not keep up with the large amount of data being collected by the large number of sample wells.

According to some implementations, a beam-steering module may receive output pulses from a mode-locked laser module and be configured to adjust at least the position and incident angles of the optical pulses onto an optical coupler (e.g., grating coupler) of a sample chip having a sample array. In some cases, the output pulses from the mode-locked laser module may be operated on by a beam-steering module to additionally or alternatively change a beam shape and/or beam rotation at an optical coupler. In some implementations, the beam-steering module may further provide focusing and/or polarization adjustments of the beam of output pulses onto the optical coupler. One example of a beam-steering module is described in U.S. patent application Ser. No. 15/161,088 titled “PULSED LASER AND BIOANALYTIC SYSTEM,” filed May 20, 2016, which is incorporated herein by reference. Another example of a beam-steering module is described in a separate U.S. patent application Ser. No. 15/843,720 “COMPACT BEAM SHAPING AND STEERING ASSEMBLY,” filed Dec. 14, 2017, which is incorporated herein by reference.

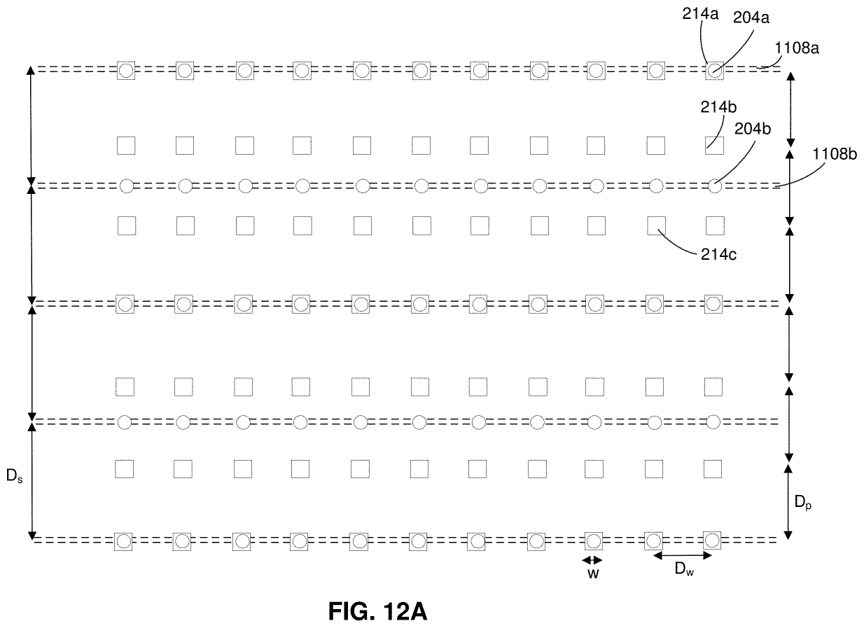

In embodiments that involve using detection system 100 for nucleic acid sequencing, luminescent molecule(s) 106 may include different types of luminescent molecules associated with different types of nucleotides or nucleotide analogs, such as by using different types of luminescent molecules to label the different types of nucleotides or nucleotide analogs. Individual sample wells in sample well array 104 may be configured to receive a template nucleic acid molecule and labeled nucleotides and/or nucleotide analogs. A non-limiting example of a sequencing reaction taking place in a sample well is depicted in FIG. 10. In this example, sequential incorporation of nucleotides and/or nucleotide analogs into a growing strand that is complementary to a target nucleic acid is taking place in the sample well. The sequential incorporation can be detected to sequence a series of nucleic acids (e.g., DNA, RNA). According to some embodiments, polymerase 1020 may be located within the sample well (e.g., attached to a base of the sample well). The polymerase may take up a target nucleic acid (e.g., a portion of nucleic acid derived from DNA), and sequence a growing strand of complementary nucleic acid to produce a growing strand of DNA. Nucleotides and/or nucleotide analogs labeled with different luminescent molecules may be dispersed in a solution above and within the sample well.

When a labeled nucleotide and/or nucleotide analog 1010 is incorporated into a growing strand of complementary nucleic acid, as depicted in FIG. 10, one or more attached luminescent molecules 1030 may be repeatedly excited by pulses of optical energy coupled into the sample well. In some embodiments, the luminescent molecule(s) 1030 may be attached to one or more nucleotides and/or nucleotide analogs 1010 with any suitable linker 1040. An incorporation event may last for a period of time up to about 100 ms. During this time, pulses of emission light resulting from excitation of the luminescent molecule(s) by pulses from an excitation source, such as a mode-locked laser, may be detected with a photon-counting photodetector. By attaching luminescent molecule(s) with different emission characteristics (e.g., emission decay rates, intensity) to the different nucleotides (A, C, G, T) or nucleotide analogs, detecting and distinguishing the different emission characteristics while the strand of DNA incorporates a nucleic acid and enables determination of the nucleotide sequence of the growing strand of DNA.

Detection circuitry 116 may be configured to count incident photons received by photodetector array 114 from sample well array 104 to distinguish between luminescent molecules associated with different nucleotides or nucleotide analogs being incorporated into a nucleic acid molecule. Detection circuitry 116 may generate signals corresponding to the different types of luminescent molecules, and a set of signals may identify a series of nucleotides labeled with the different types of luminescent molecules and may be used to sequence a template nucleic acid molecule. In particular, the series of nucleotides identified by the set of signals generated by detection circuitry 116 may correspond to a series of nucleotides of a nucleic acid molecule complementary to the template nucleic acid strand. As an example, four different fluorophores may be used to label four different types of nucleotides (e.g., nucleotides having the bases adenine “A,” guanine “G,” cytosine “C,” and thymine “T”) and detection circuitry 116 may generate four different types of signals, which are used to distinguish among the four fluorophores and identify which of the four nucleotides are incorporated into a nucleic acid molecule complementary to a template nucleic acid molecule being sequenced. In particular, the four different fluorophores may vary in fluorescence lifetime and/or intensity profile such that the signals generated by detection circuitry 116 may distinguish among the four fluorophores based on their fluorescence lifetimes and/or intensity profile. An exemplary set of signals generated by detection circuitry 116 may identify a series of nucleotides as ATTACAGG, which can be used to identify the complementary series of nucleotides as TAATGACC as being present in a template nucleic acid molecule.

Prior to performing analysis of a sample using a detection system as described herein, alignment of the sample well array and the photodetector array may need to be achieved such that at least some of the sample wells are optically positioned relative to the photodetector array for at least some of photodetectors to receive light emitted from a respective sample well. Accordingly, some embodiments of the present application relate to techniques for optically aligning the sample well array relative to the photodetector array.

Referring again to FIG. 1, in some embodiments, signals generated by detection circuitry 116 may be used in aligning sample well array 104 relative to photodetector array 114. In such embodiments, processor 118 may process signals generated by detection circuitry 116 to generate stage control signals for repositioning sample well array 104 and transmit the stage control signals to stage control circuitry 110. Stage control circuitry 110 may act to move stage 102 in response to receiving the stage control signals, and sample well array 104 on stage 102 may change positions relative to photodetector array 114. Additionally or alternatively, processor 118 may generate stage control signals for repositioning photodetector array 114 and transmit the stage control signals to stage control circuitry 128. Stage control circuitry 128 may act to move stage 126 in response to receiving the stage control signals, and photodetector array 114 may change positions relative to sample well array 104. Stage 102 and/or stage 126 may be configured to move in any suitable number of axes, including translational and rotational axes. In some embodiments, stage 102 may be a piezo stage configured to have a range of movement along three different axes. In some embodiments, stage 126 may be a stage mounted on a goniometer, which may allow stage 126 to tilt at particular angles.

Although stages 102 and 126 and associated control circuitry 110 and 128 are shown in FIG. 1, it should be appreciated that some embodiments may involve using only one stage, such as either a stage for moving sample well array 104 or a stage for moving photodetector array 114, and may only include stage control circuitry for controlling positioning of the stage. Additionally or alternatively, some embodiments may involve manual control (e.g., rotatable knobs for mechanical positioning by a user) of one or both of stages 102 and 126 for positioning sample well array 104 and/or photodetector array 114.

Signals generated by detection circuitry 116 may be provided to processor 118, which may perform analysis using the signals. The processor 118 may include data transmission hardware configured to transmit and receive data to and from external devices via one or more data communications links. In some embodiments, processor 118 may generate image data using the signals and transmit the image data to display device 120, and display device 120 may display an image using the image data. An image displayed on display device 120 may allow a user to view whether sample well array 104 is suitably aligned to photodetector array 114.

In some embodiments, sample well array 104 is integrated as part of a sample chip, where sample well array 104 is arranged on a surface of the sample chip. The sample chip may include one or more optical components for delivering excitation light 122 to individual sample wells of sample well array 104. Sample chip may include one or more waveguides positioned relative to sample wells such that some or all of the sample wells in the array are positioned to receive light from the one or more waveguides. In some embodiments, sample chip may include one or more grating couplers configured to receive light and optically couple light into the one or more waveguides. In such embodiments, a beam of incident excitation light may be directed to a region of sample chip that is separate from a region having the sample wells. Optical component(s) 112 may be configured to direct a beam of excitation light 122 towards one or more grating couplers on the sample chip, which may allow for coupling of excitation light into the one or more waveguides.

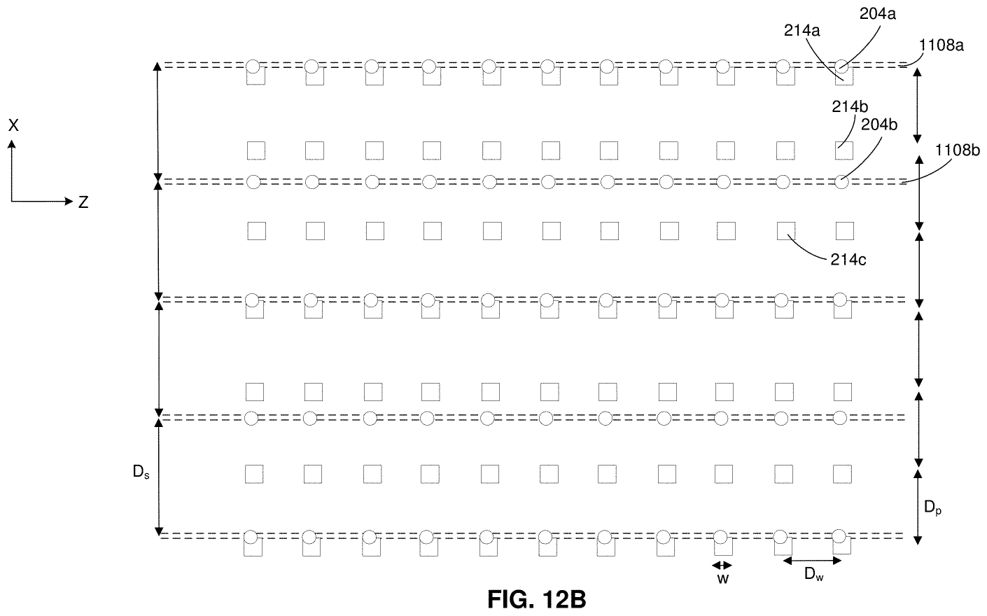

FIG. 11 is a cross-sectional view of an exemplary sample chip 1100, according to some embodiments. Sample chip 1100 includes multiple sample wells 204 arranged on a surface of sample chip 1100. The row of sample wells 204 shown in FIG. 11 are positioned a distance D from waveguide 1108 to allow for optical coupling with waveguide 1108. Distance D may be in the range of 50 nm and 500 nm, including any value or range of values in that range. In some embodiments, distance D is between 100 nm and 200 nm, including any value or range of values in that range. Although five sample wells are shown, it should be appreciated that sample chip 1100 may include any suitable number of sample wells in a cross-sectional view of sample chip 1100. In some embodiments, sample wells 204 are positioned relative to waveguide 1108 to allow for an evanescent optical field to couple optical energy to individual sample wells 204 as light propagates along waveguide 1108. Sample chip 1100 may include grating coupler 1106, which may couple excitation light 122 (shown by the dashed arrows in FIG. 11) to waveguide 1108. During operation, a beam of excitation light 122 may be positioned to couple with grating coupler 1106, such as by optical component(s) 112 as shown in FIG. 1, and light may propagate along waveguide 1108 and couple to some or all of the sample wells 204 positioned along waveguide 1108. A luminescent molecule positioned within a particular sample well 204 may receive excitation light from waveguide 1108, and in response may emit light 124, which may be detected by a photodetector 214 in photodetector array 114.

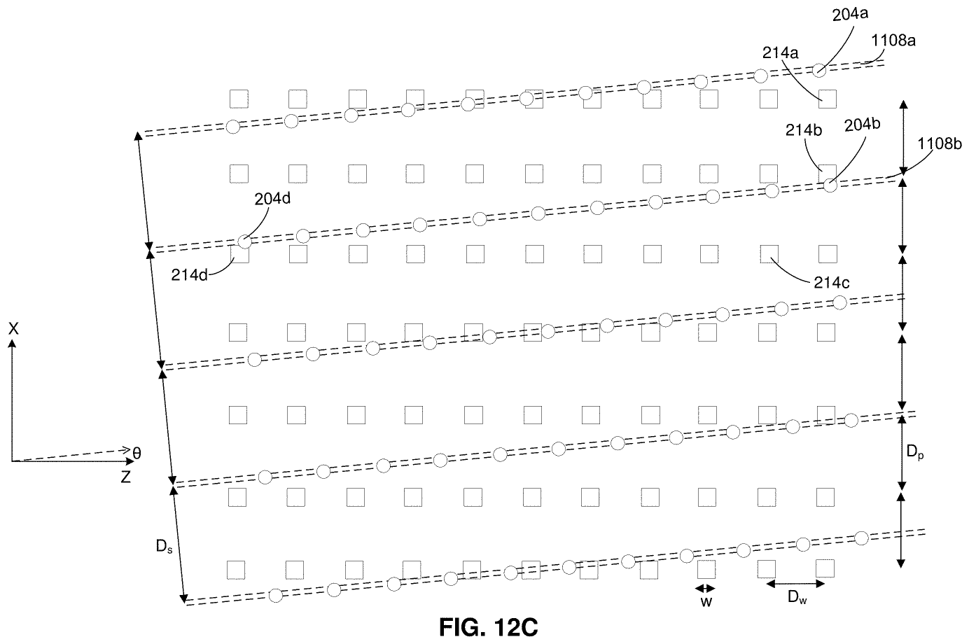

FIG. 12A is a schematic planar view illustrating optical alignment of sample wells 204 to photodetectors 214. Sample wells 204 are shown as circles and photodetectors 214 are shown as squares. However, it should be appreciated that sample wells and photodetectors may have any suitable cross-sectional shape and that aspects of the present application are not limited to the shapes of sample wells 204 and photodetectors 214 shown in FIG. 12A. Optical component(s) 112 may be configured to adjust the relative magnification between the optical plane of the sample well array and the optical plane of the photodetector array such that at least a portion of the sample wells optically overlap with at least some of the photodetectors. The arrangement of sample wells in an array, including distances between sample wells along a row and between rows of sample wells, as well as the arrangement of photodetectors in an array, including distances between photodetectors and rows of photodetectors, may have a configuration that allows for optical alignment of some or all of the sample wells to optically align with individual photodetectors. As shown in FIG. 12A, the relative spacing between individual sample wells 204 and individual photodetectors 214 may allow for at least some of the rows of sample wells in a sample well array to optically align with some of the rows of photodetectors. In some embodiments, optical alignment may involve having the distance between sample wells in a row as being the same or similar as the distance between photodetectors in a row.

Optical alignment may be considered in an optical plane that includes sample wells and/or in an optical plane that includes photodetectors. In some embodiments, an optical plane of the sample wells may have a distance D_{w} between individual sample wells along a row and between individual photodetectors along a row as being approximately 5 microns. In some embodiments, an optical plane of the photodetectors may have a distance D _{w} between individual sample wells along a row and between individual photodetectors along a row as being approximately 150 microns. Individual photodetectors may have a dimension w within which a sample well optically overlaps when in optical alignment. In some embodiments, dimension w may be approximately 1 micron in the optical plane that includes the sample wells. In some embodiments, dimension w may be approximately 30 microns in the optical plane that includes the photodetectors. The distance Dₛ between rows of sample wells and the distance Dₚ between rows of photodetectors may allow for optical alignment. In some embodiments, distance Dₛ may be in the range of approximately 7.5 microns to approximately 225 microns, or any value or range of values in that range, in the optical plane of the sample wells. In some embodiments, distance Dₚ may be in the range of approximately 5 microns to approximately 150 microns, or any value or range of values in that range, in the optical plane of the sample wells. In some embodiments, distance Dₚ may be approximately 150 microns in the optical plane of the sample wells.

Some embodiments may involve optical alignment of sample wells positioned along a waveguide to a row of photodetectors. As shown in FIG. 12A, sample wells, including sample well 204a, are positioned along waveguide 1108a and optically align with a row of photodetectors, including photodetector 214a. While another row of sample wells, such as the row of sample wells positioned along waveguide 1108b, which includes sample well 204b, is not optically aligned with individual photodetectors, such as the rows of photodetectors that include photodetector 214b and 214c. This type of configuration may allow for improved ease in aligning of sample wells to photodetectors because some of the photodetectors are used for detecting when sample wells are in alignment while other photodetectors are used for detecting when sample wells are not aligned. Adjusting the relative positioning of a sample well array to a photodetector array may include moving one or both of the arrays to a position where a first subset of the photodetectors detect a larger amount of photons while a second subset of photodetectors detect a smaller amount of photons.

FIG. 12B is a planar view illustrating optical misalignment of sample wells 204 to photodetectors 214. In particular, FIG. 12B illustrates translational misalignment with sample wells 204 offset from photodetectors 214 along the x-direction. Correcting for such translational misalignment may involve incrementally moving the sample well array along the x-direction until a row of photodetectors detects a certain amount of photons, such as a maximum amount of photons or an amount of photons above a threshold value, to achieve the alignment shown in FIG. 12A.

In some instances, optical misalignment of a sample well array and a photodetector array may include rotational misalignment. FIG. 12C is a planar view illustrating rotational misalignment of sample wells 204 to photodetectors 214 where sample wells 204 are misaligned with photodetectors 214 by an angle θ. In such a rotational misalignment position, sample wells along individual waveguides may only overlap with some of the photodetectors in a row of the photodetector array, and the misalignment can be corrected or reduced by rotating the sample well array relative to the photodetector array or by rotating the photodetector array relative to the sample well array such that more photodetectors in the row detect light. For example, as shown in FIG. 12C, only some of the sample wells along waveguide 1108a optically overlap with photodetectors in a row that includes photodetector 214a such that only those photodetectors that optically overlap with sample wells are positioned to receive photons. Correcting for such rotational misalignment may involve incrementally rotating the sample well array relative to the photodetector array so that there are more photodetectors positioned to detect light.

Additionally, as discussed above, the sample well array and the photodetector array may be designed such that not all of the rows of sample wells align with photodetectors, where such photodetectors may be considered as “dark” photodetectors. In such embodiments, correcting for rotational misalignment may involve positioning the sample well array relative to the photodetector array such that some of the rows of sample wells do not overlap with photodetectors. For example, rotational misalignment may involve a situation where a single row of sample wells is positioned to overlap with multiple rows of photodetectors. As shown in FIG. 12C, photodetectors 214b and 214d are in separate rows in the photodetector array, and sample wells 204b and 204d, which are positioned along waveguide 1108b, overlap with photodetectors 214b and 214d, respectively. Correcting for this type of rotational misalignment may involve rotating the sample well array relative to the photodetector array such that the row of sample wells along waveguide 1108b either align with a row of photodetectors or do not align with any photodetectors. Since this type of misalignment is observed by neighboring rows of photodetectors having at least one photodetector detecting light, correction may involve repositioning the sample well array and the photodetector array until the rows of photodetectors that are positioned to receive light from the sample well array are separated by one or more rows of photodetectors that are positioned to not receive light from the sample well array. In such instances, the alignment process may involve comparing the pattern of photodetectors in the photodetector array that are detecting light at any particular stage of the alignment process to a desired pattern of light being detected by the photodetector array to determine whether additional alignment steps are needed to achieve the desired pattern. As an example, the desired pattern of photodetectors detecting light with respect to FIGS. 12A, 12B, and 12C could be described as alternating between a row of photodetectors detecting light, or “light” photodetectors, with a row of photodetectors that do not detect light, or “dark” photodetectors.” This pattern could then be compared to patterns of light detection during the alignment process to determine whether the sample well array and the photodetector array have been suitably aligned. In some embodiments, a dark photodetector pattern may identify a particular orientation of the sample well array, and be used in adjusting alignment. For example, a rotationally asymmetric pattern, such as an L-shaped pattern of dark photodetectors, may be used in determining that the sample well array and the photodetector array are not rotationally aligned.

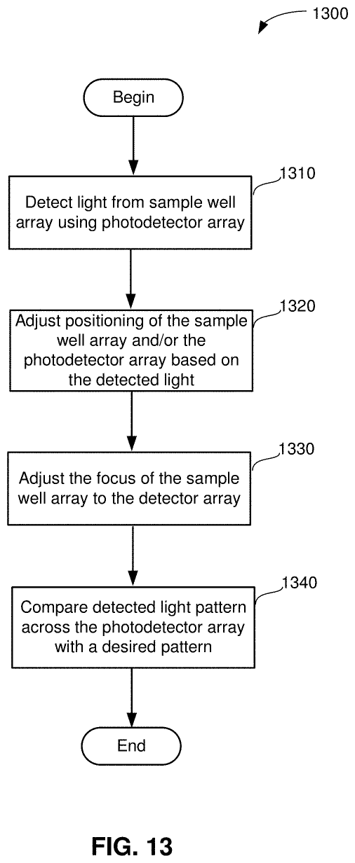

FIG. 13 is a flowchart of an illustrative process 1300 for optically aligning a sample well array to a photodetector array, in accordance with some embodiments of the technology described herein. Process 1300 begins at act 1310, where light emitted from sample wells in a sample well array, such as sample well array 104, is detected using a photodetector array, such as photodetector array 114. An amount of light detected by individual photodetectors may provide an indication of a degree of alignment of the sample well array to the photodetector array. Detecting light using the photodetector array may involve detection circuitry, such as detection circuitry 116, performing photon counting of incident photons received at individual photodetectors. In some embodiments, alignment may involve directing excitation light towards sample wells in the sample well array (e.g., propagating light along waveguides in a sample chip) and detecting light emitted from the sample wells using the photodetector array.

Next, process 1300 proceeds to act 1320, where the positioning of the sample well array and/or the photodetector array is adjusted based on the detected light such that at least some of the sample wells are optically aligned with at least some of the photodetectors. Adjusting the positioning of the sample well array and/or the photodetector array may involve adjusting to account for rotational and/or translational misalignment between the sample well array and the photodetector array. Adjusting the positioning of the sample well array may include moving the sample well array from a first position to a second position, which may involve using a stage, such as stage 102. Adjusting the positioning of the photodetector array may include moving the photodetector array from a first position to a second position, which may involve using a stage, such as stage 126. A first set of photodetectors may detect a larger amount of photons when in the second position than in the first position. A second set of photodetectors may detect a smaller amount of photons when in the second position than in the first position. In some embodiments, adjusting the positioning of the sample well array to the photodetector array may involve adjusting their relative positions such that one or more rows of sample wells optically align with one or more rows of photodetectors. It should be appreciated that the sample well array, the photodetector array or both may be repositioned during act 1320.

Next, process 1300 may proceed to act 1330, where the focus of the sample well array to the detector array is adjusted. This process may involve adjusting one or more optics in the system, such as optical component(s) 112, to bring an image plane of the sample well array in alignment with the plane of the detection regions of the photodetectors.

Next, process 1300 may proceed to act 1340, where the light pattern detected by the photodetector array is compared to a desired light pattern. In particular, act 1340 may be included in the alignment process when there are a set of photodetectors in the photodetector array designated as “dark” photodetectors. Comparison of a given light pattern detected by the photodetector array to a desired pattern may involve a one-to-one comparison of the light detected by individual photodetectors in the photodetector array with its corresponding location within the desired light detection pattern and/or comparing the given light pattern and the desired pattern overall to obtain a degree of alignment.

Some embodiments may involve repeating steps 1310, 1320, 1330, and/or 1340 to achieve a desired amount of optical alignment between sample well array and photodetector array. In some embodiments, adjusting a position of sample well array, photodetector array or both in act 1320 may be an incremental change in position, which may be subsequently assessed as to whether the repositioning improves alignment by detecting light from the sample well array using the photodetector array. If the new position does improve optical alignment, then the new position may be kept. If the new position does not improve optical alignment, then the system may revert back to a prior position. In this manner, alignment of the sample well array to the photodetector array may proceed in increments.

In some embodiments, some or all of process 1300 may be performed by any suitable computing device(s) (e.g., a single computing device, multiple computing devices co-located in a single physical location or located in multiple physical locations remote from one another, etc.), as aspects of the technology described herein are not limited in this respect. In some embodiments, some or all of process 1300 may be performed by a user operating one or more components of a detection system, such as detection system 100. For example, stage 102, stage 126 or both may be controlled by one or more computing devices, which may generate and transmit control signals to the stages.

In should be appreciated that the techniques described herein for aligning a photodetector array to a sample well array may be implemented in forming a monolithic device where forming the monolithic device involves bonding together two separate substrates: one substrate having a photodetector array and another substrate having a sample well array, or other array configured to emit light from particular locations. In this context, forming the monolithic device may involve positioning of the two substrates relative to one another such that some or all of the photodetectors on the first substrate optically align with sample wells, or other points of interest, on the second substrate prior to bonding the two substrates. It is at this step in forming the monolithic device where the alignment techniques described herein may be implemented to achieve a desired degree of functionality in the resulting monolithic device. In some embodiments, the two substrates may be brought in physical contact and light detected by the photodetector array may be used in adjusting the alignment of the photodetector array with the sample well array. In some embodiments, these alignment techniques may be used in aligning optical components, such as microlens arrays and fiber arrays, to light source arrays (e.g., vertical-cavity surface-emitting lasers (VCSELs)).

### Additional Aspects

In some embodiments, techniques described herein may be carried out using one or more computing devices. Embodiments are not limited to operating with any particular type of computing device.

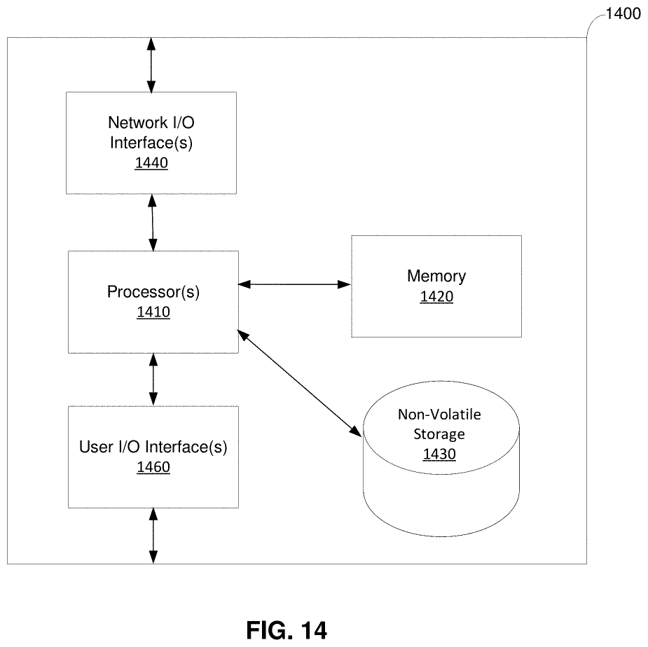

FIG. 14 is a block diagram of an illustrative computing system 1400 that may be used to implement a control circuit for controlling the photodetector array, the detection circuitry, one or more light sources, a stage for positioning the sample well array, or for performing analysis of data from the photodetector array. Computing system 1400 includes processor(s) 1410 and one or more articles of manufacture that comprise non-transitory computer-readable storage media (e.g., memory 1420 and one or more non-volatile storage media 1430). Processor(s) 1410 may control writing data to and reading data from the memory 1420 and the non-volatile storage 1430 in any suitable manner, as the aspects of the technology described herein are not limited in this respect. To perform any of the functionality described herein, processor(s) 1410 may execute one or more processor-executable instructions stored in one or more non-transitory computer-readable storage media (e.g., the memory 1420), which may serve as non-transitory computer-readable storage media storing processor-executable instructions for execution by the processor(s) 1410.

Computing system 1400 may also include network input/output (I/O) interface(s) 1440 via which computing system 1400 may communicate with other computing devices (e.g., over a network). Computing system 1400 may include user input/output (I/O) interface(s) 1460, via which computing system 1400 may provide output to and receive input from a user. The user I/O interface(s) 1460 may include devices such as a keyboard, a mouse, a microphone, a display device (e.g., a monitor or touch screen), speakers, a camera, and/or various other types of I/O devices.

The above-described embodiments can be implemented in any of numerous ways. For example, the embodiments may be implemented using hardware, software or a combination thereof. When implemented in software, the software code can be executed on any suitable processor (e.g., a microprocessor) or collection of processors, whether provided in a single computing device or distributed among multiple computing devices. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of the embodiments described herein comprises at least one computer-readable storage medium (e.g., RAM, ROM, EEPROM, flash memory or other memory technology, CD-ROM, digital versatile disks (DVD) or other optical disk storage, magnetic cassettes, magnetic tape, magnetic disk storage or other magnetic storage devices, or other tangible, non-transitory computer-readable storage medium) encoded with a computer program (e.g., a plurality of executable instructions) that, when executed on one or more processors, performs the above-discussed functions of one or more embodiments. The computer-readable medium may be transportable such that the program stored thereon can be loaded onto any computing device to implement aspects of the techniques described herein. In addition, it should be appreciated that the reference to a computer program which, when executed, performs any of the above-discussed functions, is not limited to an application program running on a host computer. Rather, the terms computer program and software are used herein to reference any type of computer code (e.g., application software, firmware, microcode, or any other form of computer instruction) that can be employed to program one or more processors to implement aspects of the techniques described herein.

The described embodiments can be implemented in various combinations. Example configurations include configurations (1)-(36), (40)-(42), and (51)-(56), and methods (37)-(39) and (43)-(50) below.

(1) A system comprising: an array of photodetectors; and detection circuitry associated with the array of photodetectors, the detection circuitry being configured to count, during a first time period and a second time period following illumination of a luminescent molecule with excitation light, a quantity of incident photons received from the luminescent molecule at a photodetector of the array of photodetectors.

(2) The system of configuration (1), wherein the detection circuitry is configured to count single photons incident to the array of photodetectors during the first time period and the second time period.

(3) The system of configuration (1) or (2), wherein the detection circuitry is further configured to generate signals identifying the luminescent molecule.

(4) The system of any one of configurations (1)-(3), wherein the detection circuitry is further configured to generate signals distinguishing among different types of luminescent molecules including a first signal identifying a first type of luminescent molecule and a second signal identifying a second type of luminescent molecule.

(5) The system of configuration (4), wherein the different types of luminescent molecules are associated with different nucleotides, and the detection circuitry is configured to generate a set of signals identifying a series of nucleotides.

(6) The system of configuration (5), wherein the set of signals identifying the series of nucleotides sequences a template nucleic acid molecule.

(7) The system of configuration (6), wherein the series of nucleotides identified by the set of signals is a series of nucleotides of a nucleic acid molecule complementary to the template nucleic acid molecule.

(8) The system of configuration (7), wherein different types of nucleotides in the series of nucleotides are labeled with the different types of luminescent molecules.

(9) The system of any one of configurations (1)-(8), wherein the detection circuitry is further configured to generate signals indicative of a lifetime of the luminescent molecule.

(10) The system of any one of configurations (1)-(9), wherein the detection circuitry has at least two photon counting circuits associated with a photodetector in the array and is configured to count the quantity of incident photons received by the photodetector.

(11) The system of configuration (10), wherein the detection circuitry is further configured to generate signals indicative of the quantity of incident photons received by the photodetector during the first time period and the second time period.

(12) The system of configuration (11), wherein the signals generated by the detection circuitry include a first signal identifying a first quantity of incident photons received by the photodetector during the first time period and a second signal identifying a second quantity of incident photons received by the photodetector during the second time period.

(13) The system of configuration (12), wherein the at least two photon counting circuits includes a first photon counting circuit and a second photon counting circuit, and wherein the first photon counting circuit is configured to generate the first signal and the second photon counting circuit is configured to generate the second signal.

(14) The system of configuration (12) or (13), wherein the detection circuitry is configured to generate a readout signal that includes the first signal and the second signal.

(15) The system of any one of configurations (12)-(14), wherein the first time period and the second time period are non-overlapping time periods.

(16) The system of any one of configurations (1)-(15), wherein the detection circuitry is configured to receive a control signal indicating a reference time and perform photon counting in response to receiving the control signal.

(17) The system of any one of configurations (1)-(16), wherein the detection circuitry is configured to receive a control signal from a light source configured to emit a pulse of the excitation light and perform photon counting in response to receiving the control signal.

(18) The system of any one of configurations (1)-(17), wherein the system further comprises: at least one light source configured to emit the excitation light; and circuitry configured to control the at least one light source to emit pulses of excitation light and generate control signals corresponding to the emitted pulses, wherein the detection circuitry associated with a photodetector in the array is configured to perform photon counting in response to receiving at least one of the control signals from the circuitry.

(19) The system of any one of configurations (1)-(18), wherein the system further comprises: an array of sample wells, wherein individual sample wells in the array of sample wells are configured to receive a sample.

(20) The system of configuration (19), wherein an alignment position of the array of sample wells to the array of photodetectors includes a first subset of sample wells positioned to optically align with at least a portion of the photodetectors in the photodetector array and a second subset of sample wells positioned to not optically align with photodetectors in the array of photodetectors.

(21) The system of configuration (20), wherein the first subset of sample wells includes at least one row of sample wells in the array of sample wells that optically aligns with at least one row of photodetectors in the array of photodetectors when in the alignment position.

(22) The system of configuration (20) or (21), wherein the first subset of sample wells includes a first row and a second row of sample wells in the array of sample wells, wherein the first row and the second row are separated by at least one row of sample wells in the second subset of sample wells.

(23) The system of any one of configurations (19)-(22), wherein the system further comprises at least one optic positioned to direct photons emitted from the array of sample wells towards the array of photodetectors.

(24) The system of configuration (23), wherein the at least one optic is positioned to direct photons emitted from one sample well of the array of sample wells to one photodetector in the array of photodetectors.

(25) The system of configuration (23) or (24), wherein the at least one optic is configured to align photons emitted from one sample well of the array of sample wells to overlap with a detection region of one photodetector in the array of photodetectors.

(26) The system of any one of configurations (23)-(25), wherein the at least one optic includes a dichroic mirror positioned to direct light emitted by at least one light source towards the array of sample wells and transmit light emitted by the luminescent molecule to the array of photodetectors.

(27) The system of any one of configurations (23)-(26), wherein the at least one optic includes a plurality of lenses arranged in a relay lens configuration.

(28) The system of any one of configurations (19)-(27), wherein the system further comprises at least one waveguide, wherein at least a portion of the sample wells in the array of sample wells are positioned to receive light from the at least one waveguide.

(29) The system of configuration (28), wherein the array of sample wells and the at least one waveguide are integrated on a sample chip, the array of sample wells being arranged on a surface of the sample chip.

(30) The system of configuration (29), wherein the sample chip further comprises a grating coupler configured to receive light from an external light source and optically couple light into the at least one waveguide.

(31) The system of any one of configurations (1)-(30), wherein the array of photodetectors comprises an array of single-photon avalanche photodiodes.

(32) An apparatus comprising: detection circuitry comprising an array of photodetectors, the detection circuitry being configured to count incident photons received by the array of photodetectors from luminescent molecules to distinguish between the luminescent molecules associated with different nucleotides being incorporated into a nucleic acid molecule.

(33) The apparatus of configuration (32), wherein the detection circuitry is further configured to generate signals identifying a series of nucleotides as individual nucleotides are incorporated into the nucleic acid molecule.

(34) The apparatus of configuration (32) or (33), wherein the luminescent molecules label different types of nucleotides.

(35) The apparatus of any one of configurations (32)-(34), wherein the apparatus further comprises a plurality of sample wells configured to receive a template nucleic acid molecule, wherein one photodetector in the array is positioned receive light from one of the plurality of sample wells.

(36) The apparatus of configuration (35), wherein the nucleic acid molecule is complementary to the template nucleic acid molecule.

(37) A photodetection method comprising: receiving, by a photodetector in an array of photodetectors, photons from a luminescent molecule; and counting, using detection circuitry, a quantity of photons incident to the photodetector during a first time period and a second time period.

(38) The photodetection method of (37), further comprising: generating signals identifying the luminescent molecule, wherein the signals indicate a first quantity of photons received by the photodetector during the first time period and a second quantity of photons received by the photodetector during the second time period.

(39) The photodetection method of (37) or (38), further comprising: illuminating the sample with a pulse of excitation light, and wherein counting the quantity of photons occurs in response to illuminating the sample with a pulse of excitation light.

(40) At least one non-transitory computer-readable storage medium storing processor-executable instructions that, when executed by at least one hardware processor, cause the at least one hardware processor to perform a photodetection method comprising: receiving, from circuitry configured to control at least one light source, a control signal corresponding to a pulse of light emitted by the at least one light source; and controlling, in response to receiving the control signal, detection circuitry configured to perform counting of photons incident to a photodetector in an array of photodetectors, wherein the counting includes counting a quantity of incident photons received by the detector during a first time period and a second time period.

(41) The at least one non-transitory computer-readable storage medium of (40), wherein the detection circuitry is further configured to generate signals indicative of the quantity of incident photons received by the photodetector during the first time period and the second time period.

(42) The at least one non-transitory computer-readable storage medium of (40) or (41), wherein the signals generated by the detection circuitry include a first signal identifying a first quantity of incident photons received by the photodetector during the first time period and a second signal identifying a second quantity of incident photons received by the photodetector during the second time period.

(43) A method for aligning an array of sample wells to an array of photodetectors, the method comprising: detecting, using the array of photodetectors, light from the array of sample wells incident to the array of photodetectors; and adjusting, based on the detected light, the positioning of the array of sample wells to the array of photodetectors to allow at least a portion of sample wells in the array of sample wells to optically align with at least a portion of the photodetectors in the array of photodetectors.

(44) The method of (43), wherein an amount of light detected by individual photodetectors in the array of photodetectors indicates a degree of alignment of the array of sample wells to the array of photodetectors.

(45) The method of (43) or (44), wherein adjusting the positioning of the array of sample wells to the array of photodetectors includes moving the array of sample wells from a first position to a second position, wherein a first subset of the photodetectors in the array of photodetectors detect a larger amount of photons when the array of sample wells is in the second position than in the first position.

(46) The method of (45), wherein a second subset of the photodetectors in the array of photodetectors detect a smaller amount of photons when the array of sample wells is in the second position than in the first position.

(47) The method of any one of (43)-(46), wherein adjusting the positioning of the array of sample wells to the array of photodetectors comprises positioning at least one row of sample wells in the array of sample wells to optically align with at least one row of photodetectors in the array of photodetectors.

(48) The method of any one of (43)-(47), wherein adjusting the positioning of the array of sample wells to the array of photodetectors comprises moving the array of sample wells and/or the array of photodetectors in a translational direction.

(49) The method of any one of (43)-(48), wherein adjusting the positioning of the array of sample wells to the array of photodetectors comprises rotating the array of sample wells and/or the array of photodetectors at an angle.

(50) The method of any one of (43)-(49), wherein adjusting the positioning of the array of sample wells to the array of photodetectors comprises comparing a pattern of the detected light to an alignment pattern, the alignment pattern having at least one of the photodetectors as detecting an amount of light below a threshold.

(51) A system comprising: a stage; an array of photodetectors configured to detect light; detection circuitry associated with the array of photodetectors and configured to generate signals indicative of photons incident to the array of photodetectors; and circuitry configured to perform a method comprising: receiving the signals from the detection circuitry; and adjusting, based on the received signals, the positioning of the stage relative to the array of photodetectors to allow at least a portion of sample wells in the array of sample wells to optically align with at least a portion of the photodetectors in the array of photodetectors.

(52) The system of configuration (51), wherein the circuitry comprises: at least one processor; and at least one computer-readable storage medium encoded with computer-executable instructions that, when executed, perform the method.

(53) The system of configuration (51) or (52), wherein the received signals indicate an amount of light detected by individual photodetectors in the array of photodetectors, and the amount of light indicates a degree of alignment of the array of sample wells to the array of photodetectors.

(54) The system of any one of configurations (51)-(53), wherein adjusting the positioning of the stage relative to the array of photodetectors further comprises adjusting the position of the stage from a first position to a second position, wherein a first subset of the photodetectors in the array of photodetectors detect a larger amount of photons when the stage is in the second position than in the first position.

(55) The system of configuration (54), wherein a second subset of the photodetectors in the array of photodetectors detect a smaller amount of photons when the array of sample wells is in the second position than in the first position.

(56) The system of configuration (55), wherein adjusting the positioning of the array of sample wells to the array of photodetectors comprises positioning at least one row of sample wells in the array of sample wells to align with at least one row of photodetectors in the array of photodetectors.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

What is claimed is:

1. A system comprising:
an array of photodetectors; and
detection circuitry associated with the array of photodetectors, the detection circuitry being configured to count, during a first time period and a second time period following illumination of a luminescent molecule with excitation light, a quantity of incident photons received from the luminescent molecule at a photodetector of the array of photodetectors.

2. The system of claim 1, wherein the detection circuitry is configured to count single photons incident to the array of photodetectors during the first time period and the second time period.

3. The system of claim 1, wherein the detection circuitry is further configured to generate signals identifying the luminescent molecule.

4. The system of claim 1, wherein the detection circuitry is further configured to generate signals distinguishing among different types of luminescent molecules including a first signal identifying a first type of luminescent molecule and a second signal identifying a second type of luminescent molecule.

5. The system of claim 4, wherein the different types of luminescent molecules are associated with different nucleotides, and the detection circuitry is configured to generate a set of signals identifying a series of nucleotides.

6. The system of claim 5, wherein the set of signals identifying the series of nucleotides sequences a template nucleic acid molecule.

7. The system of claim 6, wherein the series of nucleotides identified by the set of signals is a series of nucleotides of a nucleic acid molecule complementary to the template nucleic acid molecule.

8. The system of claim 7, wherein different types of nucleotides in the series of nucleotides are labeled with the different types of luminescent molecules.

9. The system of claim 1, wherein the detection circuitry is further configured to generate signals indicative of a lifetime of the luminescent molecule.

10. The system of claim 1, wherein the detection circuitry has at least two photon counting circuits associated with a photodetector in the array and is configured to count the quantity of incident photons received by the photodetector.

11. The system of claim 10, wherein the detection circuitry is further configured to generate signals indicative of the quantity of incident photons received by the photodetector during the first time period and the second time period.

12. The system of claim 11, wherein the signals generated by the detection circuitry include a first signal identifying a first quantity of incident photons received by the photodetector during the first time period and a second signal identifying a second quantity of incident photons received by the photodetector during the second time period.

13. The system of claim 12, wherein the at least two photon counting circuits includes a first photon counting circuit and a second photon counting circuit, and wherein the first photon counting circuit is configured to generate the first signal and the second photon counting circuit is configured to generate the second signal.

14. The system of claim 12, wherein the detection circuitry is configured to generate a readout signal that includes the first signal and the second signal.

15. The system of claim 12, wherein the first time period and the second time period are non-overlapping time periods.

16. The system of claim 1, wherein the detection circuitry is configured to receive a control signal indicating a reference time and perform photon counting in response to receiving the control signal.

17. The system of claim 1, wherein the detection circuitry is configured to receive a control signal from a light source configured to emit a pulse of the excitation light and perform photon counting in response to receiving the control signal.

18. The system of claim 1, further comprising:
at least one light source configured to emit the excitation light; and
circuitry configured to control the at least one light source to emit pulses of excitation light and generate control signals corresponding to the emitted pulses, wherein the detection circuitry associated with a photodetector in the array is configured to perform photon counting in response to receiving at least one of the control signals from the circuitry.

19. The system of claim 1, further comprising:
an array of sample wells, wherein individual sample wells in the array of sample wells are configured to receive a sample.

20. The system of claim 19, wherein an alignment position of the array of sample wells to the array of photodetectors includes a first subset of sample wells positioned to optically align with at least a portion of the photodetectors in the photodetector array and a second subset of sample wells positioned to not optically align with photodetectors in the array of photodetectors.

21. The system of claim 20, wherein the first subset of sample wells includes at least one row of sample wells in the array of sample wells that optically aligns with at least one row of photodetectors in the array of photodetectors when in the alignment position.

22. The system of claim 20, wherein the first subset of sample wells includes a first row and a second row of sample wells in the array of sample wells, wherein the first row and the second row are separated by at least one row of sample wells in the second subset of sample wells.

23. The system of claim 19, further comprising:
at least one optic positioned to direct photons emitted from the array of sample wells towards the array of photodetectors.

24. The system of claim 23, wherein the at least one optic is positioned to direct photons emitted from one sample well of the array of sample wells to one photodetector in the array of photodetectors.

25. The system of claim 23, wherein the at least one optic is configured to align photons emitted from one sample well of the array of sample wells to overlap with a detection region of one photodetector in the array of photodetectors.

26. The system of claim 23, wherein the at least one optic includes a dichroic mirror positioned to direct light emitted by at least one light source towards the array of sample wells and transmit light emitted by the luminescent molecule to the array of photodetectors.

27. The system of claim 23, wherein the at least one optic includes a plurality of lenses arranged in a relay lens configuration.

28. The system of claim 19, further comprising:
at least one waveguide, wherein at least a portion of the sample wells in the array of sample wells are positioned to receive light from the at least one waveguide.

29. The system of claim 28, wherein the array of sample wells and the at least one waveguide are integrated on a sample chip, the array of sample wells being arranged on a surface of the sample chip.

30. The system of claim 29, wherein the sample chip further comprises a grating coupler configured to receive light from an external light source and optically couple light into the at least one waveguide.

31. The system of claim 1, wherein the array of photodetectors comprises an array of single-photon avalanche photodiodes.

32. A photodetection method comprising:
receiving, by a photodetector in an array of photodetectors, photons from a luminescent molecule; and
counting, using detection circuitry, a quantity of photons incident to the photodetector during a first time period and a second time period.

33. The photodetection method of claim 32, further comprising:
generating signals identifying the luminescent molecule, wherein the signals indicate a first quantity of photons received by the photodetector during the first time period and a second quantity of photons received by the photodetector during the second time period.

34. The photodetection method of claim 32, further comprising:
illuminating the sample with a pulse of excitation light, and wherein counting the quantity of photons occurs in response to illuminating the sample with a pulse of excitation light.

35. At least one non-transitory computer-readable storage medium storing processor-executable instructions that, when executed by at least one hardware processor, cause the at least one hardware processor to perform a photodetection method comprising:
receiving, from circuitry configured to control at least one light source, a control signal corresponding to a pulse of light emitted by the at least one light source; and
controlling, in response to receiving the control signal, detection circuitry configured to perform counting of photons incident to a photodetector in an array of photodetectors, wherein the counting includes counting a quantity of incident photons received by the detector during a first time period and a second time period.

36. The at least one non-transitory computer-readable storage medium of claim 35, wherein the detection circuitry is further configured to generate signals indicative of the quantity of incident photons received by the photodetector during the first time period and the second time period.

37. The at least one non-transitory computer-readable storage medium of claim 36, wherein the signals generated by the detection circuitry include a first signal identifying a first quantity of incident photons received by the photodetector during the first time period and a second signal identifying a second quantity of incident photons received by the photodetector during the second time period.
